(19) United States
(12) Patent Application Publication
(10) Pub. No.: US 2024/0117096 A1
(43) Pub. Date: Apr. 11, 2024

(54) DEVICES AND METHODS INVOLVING STABLE OR STRETCHABLE POLYMER

(71) Applicant: The Board of Trustees of the Leland Stanford Junior University, Stanford, CA (US)

(72) Inventors: Yu Zheng, Stanford, CA (US); Zhenan Bao, Stanford, CA (US)

(21) Appl. No.: 18/221,998

(22) Filed: Jul. 14, 2023

Related U.S. Application Data
(60) Provisional application No. 63/389,304, filed on Jul. 14, 2022.

(51) Int. Cl. C08F 283/00; H10K 10/46; H10K 85/10

(52) U.S. Cl. CPC C08F 283/00; H10K 10/46; H10K 85/113; H10K 85/151

(57) ABSTRACT

Aspects involve a stretchable composite film including a polymer material having at least a portion of the polymer material being densified through covalently-attached fluorination molecules. In certain specific examples, fluorinated molecules are covalently attached to a surface region, in the form of a layer or film (e.g., polymer semiconductor (PSC) film of a transistor substrate) to facilitate operational stability and/or to encapsulation performance (e.g., stretchability-related performance). In certain other specific examples, the surface region and a fluorinated layer are used in a cooperative configuration to provide stability in the PSC film in one or more harsh environments characterized by one or more of humid air, and immersion of the PSC film in a bio-based fluid.

### FEDERALLY-SPONSORED RESEARCH AND DEVELOPMENT

This invention was made with Government support under contract FA9550-21-1-0413 awarded by the Air Force Office of Scientific Research. The Government has certain rights in the invention.

### BACKGROUND

Aspects of the present disclosure are related generally to the field of applied polymer materials (e.g., as applied to electronics) and more particularly to stable and/or stretchable polymers (e.g., sometimes “PSCs” representing polymer semiconductors and/or polymer semiconductor-based electronics). PSCs are a promising class of materials to enable soft and stretchable electronics. Despite significant progresses made on mechanical robustness, poor environmental stability remains a longstanding fundamental challenge obstructing their commercialization. One example PSC technology is used in connection with electronic skin (eSkin)-like electronics. Using this technology type for ease of discussion, it has been appreciated that eSkin-like electronics have shown great potential in advanced wearable and implantable applications, ranging from real-time health monitoring, robotic sensory skins, and medical treatments. Given the distinct advantages of mechanical robustness, low-cost solution processability and chemical tunability, polymer semiconductors (PSCs) have thus been extensively studied to achieve such soft, conformable and stretchable electronics. However, a fundamental and longstanding challenge for tangible commercialization of polymer electronics remains, namely its robustness for long-term utilization.

Compared to inorganic or organic small-molecule semiconductors, PSCs are unfortunately prone to environmental and operational degradation over extended duration. This occurs due to the large free volume within polymer thin films and the associated fast diffusion of environmental species (e.g., water, oxygen, ions and chemical impurities), resulting in mobile charge trapping and electrical properties degradation. Water has been identified as the main cause for the PSCs instability. Another less discussed issue is morphological instability, which originates from polymer chain relaxation and disrupted interchain packing. Approaches to address water instabilities (without modifying PSC chemical structure) remain limited, which include physical encapsulation of the whole device with low-permeability polymers, and blending PSCs with molecular additives. These additives are used to displace water-filled voids or to act as dopants. However, issues remain with currently employed methods during long-term use, such as increased device thickness and interfacial delamination under mechanical deformation, metastable morphology or continuous water back-diffusion. Additionally, most of the reported systems only demonstrated improvement of air stability. For practical wearable and implantable applications, specific examples have the PSC operating reliably under harsher conditions, such as direct contact with physiological environment, including water and biofluids. However, long-term stability monitoring of PSCs in such above-mentioned physiological environment remains largely under investigated.

While attachment of perfluorinated chains has been reported to introduce certain advantageous properties, surface modification of PSC films remains quite challenging due to the lack of reactive groups on its surface. The reported approaches have been indicated as being unreliable or resulting in low density of surface reactive groups and low charge carrier mobility of ˜0.1-0.2 cm² V⁻¹ s⁻¹.

Accordingly, the above discussion highlights issues which are addressed and/or benefited by example aspects and embodiments of the present disclosure.

### SUMMARY

Various example aspects and embodiments presented by the present disclosure are directed to issues such as those addressed above and/or others which may become apparent from the following disclosure. In one specific example, a method involves providing, and/or an electronic device is characterized as having, a fluorinated layer (which may or may not be a monolayer) covalently attached to a surface region, in the form of a layer or film (e.g., polymer semiconductor (PSC) film) to facilitate operational stability and/or to encapsulation performance (e.g., stretchability-related performance). In various specific examples, the fluorinated layer is covalently attached to the surface region to densify at least a portion of the region, and/or the surface region and the fluorinated layer are used in a cooperative configuration to provide stability in the PSC film in one or more harsh environments characterized by one or more of humid air, and immersion of the PSC film in a bio-based fluid (e.g., sweat, saliva, blood serum, urine and/or interstitial fluid).

In more specific examples related to the above methodology and/or devices also according to the present disclosure, an apparatus includes a polymer (e.g., PSC) film. In one such example, the film is a stretchable composite film including a polymer material having at least a portion of the polymer material being densified through covalently-attached fluorination molecules, and (optionally at a later stage of implementation, use or manufacture), the apparatus may be part of an electronic device to which the composite film is attached, wherein the electronic device is operationally stable due to the covalently-attached fluorination molecules, and the polymer material is characterized as being non-conjugated and with crystalline packing.

In another specific example of such an apparatus, the electronic device is characterized in being operationally stable due to a fluorinated layer being covalently attached to the PSC film and in having a surface reactive sites and morphology being fixed simultaneously. In a more-specific example, the fluorinated layer includes fluorinated molecules uniformly dispersed on film surface, and/or the fluorinated layer is to provide a base surface or platform for one or more subsequent modifications.

In certain other examples which may also build on the above-discussed aspects, such an apparatus includes: a semiconductor, wherein the PSC film and the fluorinated layer are cooperatively configured as part of a composite semiconductor film of the semiconductor; a semiconductor having a rubber matrix phase in a crosslinked composite semiconductor film, wherein the rubber matrix phase in a crosslinked composite semiconductor film includes the PSC film and the fluorinated layer being cooperatively configured; and/or an organic-field-effect transistor (OFET) wherein the PSC film, including the covalently-attached fluorinated layer, is as part of a composite semiconductor film of the OFET.

In related method-specific aspects, a rubber matrix phase in composite semiconductor film is used to provide anchoring sites to facilitate covalent grafting.

In certain other examples which may also build on the above-discussed aspects relating to one or more of the above types of apparatuses: the PSC film and the fluorinated layer are cooperatively configured as part of a composite semiconductor film of an organic-field-effect transistor (OFET) characterized by a charge carrier mobility that is maintainable at or above ˜1 cm²·V⁻¹·s⁻¹; the PSC film includes a crosslinked composite semiconductor portion, and further including covalently-grafted perfluorinated chains attached on the crosslinked composite semiconductor portion; and/or the PSC film, with the fluorinated layer covalently attached to the PSC film, is characterized in that the PSC film maintains substantially the same level of stretchability and charge transport mobility after N stretching-releasing cycles under at least 50% strain, wherein N is an integer in a range from 2 to 1000.

In a more specific aspect, the above type of structure or method is characterized in that: non-conjugated C═C bonds are used as reactive sites on the PSC film and a PSC is crosslinked with perfluorophenyl azide end-capped polybutadiene; the PSC film and the fluorinated layer are cooperatively configured as part of a composite semiconductor film having conjugated polymer (e.g., a donor-acceptor conjugated polymer) interpenetrating with a crosslinked rubber matrix or having a rubber matrix phase in a crosslinked composite semiconductor film; non-conjugated C═C bonds are introduced (during a method of manufacturing the PSC film) as reactive sites on the PSC film and subsequent surface fluorination is performed by initiating a thiol-ene reaction between the non-conjugated C═C bonds and perfluorodecanethiol (PFDT) via UV light (e.g., azide, alkyne, benzophenone, thiol may be introduced and then subsequent surface modification may be performed by reaction between the reactive sites and a fluorinated or hydrophobic reactive molecule via UV light or heat); and/or the PSC film and the fluorinated layer are cooperatively configured as part of a composite semiconductor film of an organic-field-effect transistor (OFET) type semiconductor with the OFET being characterized by a charge carrier mobility that is maintainable at or above ˜1 cm²·V⁻¹·s⁻¹.

In certain of these specific example embodiments, the fluorinated semiconductor film is highly stretchable and elastic, while exhibiting an increased charge transport mobility and, accordingly such exemplary aspects and embodiments of the present disclosure enable highly stable and robust, that is environment-insensitivity, stretchable polymer electronics for everyday practical applications.

In other more-specific examples, some of these disclosed aspects are directed to methods and devices that use or leverage from covalent attachment of fluorinated layer onto a (e.g., PSC or other type of) film surface to substantially improve its operational stability under various environmental conditions over an extended period. In connection with certain experimental embodiments of the present disclosure, it has been quantitatively demonstrated that in connection with or because of super-hydrophobicity through the introduced perfluorinated chains, the fluorinated film can be effectively protected and/or encapsulated against the absorption and diffusion of water and biofluids. Adding this fluorinated layer leads to a stable film surface charge carrier mobility of ˜1 cm²·V⁻¹·s⁻¹, even after storing in humid air for up to 56 days or immersing in water or artificial sweat for up to 42 days. The protection effect of fluorinated layer for transistors outperformed various stretchable polymer encapsulants, with constant bias stressing applied in air. Furthermore, the fluorinated layer improves the film surface abilities and/or stability against photo-degradation in air.

In addition to being used with semiconductor materials, other exemplary aspects and embodiments of the present disclosure are directed to use on and/or with different electronic materials in a device to further improve stability. Example materials in this context include conductor, dielectric, substrate and encapsulation layer. In some cases, the material itself has reactive sites (C═C) for grafting. In yet other specific examples, the material is blended with another matrix which has reactive sites (C═C) for grafting. In addition to fluorinated molecules, other grafting molecules that retard water diffusion can also be used to improve device stability, and aspects of the technology of the present disclosure are used to realize and demonstrate the efficiency of thiol-ene reaction to graft the layer. Various exemplary grafting molecules are disclosed herein, and examples of such matrices useful in this regard are also disclosed herein.

The above discussion is not intended to describe each aspect, embodiment or every implementation of the present disclosure. The figures and detailed description that follow also exemplify various embodiments.

### BRIEF DESCRIPTION OF FIGURES

Various example embodiments, including experimental examples, may be more completely understood in consideration of the following detailed description and in connection with the accompanying drawings, each in accordance with the present disclosure, in which:

FIGS. 1A and 1B are illustrations of a fluorinated semiconductor film achieving long-term environmental stability, according to certain exemplary aspects of the present disclosure, where FIG. 1A schematically shows an example fluorinated semiconductor film having PFDT covalently grafted thereon, and FIG. 1B shows the fluorinated film being stretchable and elastic while exhibiting stable characteristics in various harsh environmental conditions over time.

FIGS. 2A, 2B, 2C, 2D, 2E and 2F are graphs to illustrate various aspects of one or more processes, according to certain exemplary aspects of the present disclosure, involving fabrication of PSC surface fluorination;

FIGS. 3A, 3B, 3C, 3D, 3E and 3F are graphs to illustrate various morphological and mechanical properties and/or related characterizations of PSC surface fluorination, according to certain exemplary aspects of the present disclosure;

FIGS. 4A, 4B, 4C and 4D are graphs showing respective sets of characteristics for bottom-gate top-contact transistors, according to certain exemplary aspects of the present disclosure;

FIGS. 5A, 5B, 5C, 5D, 5E and 5F are graphs relating to stability in air according to certain exemplary aspects of the present disclosure, and showing respective sets of characteristics of certain semiconductor films;

FIGS. 5G, 5H, 5I, 5J and 5K are graphs and related depictions of characteristics pertaining to semiconductor films supported on a substrate, also according to certain exemplary aspects of the present disclosure;

FIGS. 6A, 6B, 6C, 6D, 6E, 6F, 6G, 6H and 6I are graphs also relating to stability (e.g., in long-term water, sweat and photochemical stability) according to certain exemplary aspects of the present disclosure, and showing respective sets of characteristics of certain semiconductor films;

FIGS. 7A and 7B are graphs respectively showing sets of characteristics for a crosslinked semiconductor film and for a fluorinated semiconductor film, according to certain exemplary aspects of the present disclosure;

FIGS. 8A, 8B, 8C and 8D are graphs respectively showing sets of characteristics for water contact angles of: (FIG. 8A) crosslinked film, and (FIG. 8B) fluorinated film, and sets of characteristics for Toluene contact angles of the (FIG. 8C) crosslinked film and (FIG. 8D) fluorinated film, also according to certain exemplary aspects of the present disclosure; and

FIGS. 9A and 9B are sets of representative transfer curves from a bottom-gate top-contact stretchable transistor with a fluorinated film as the semiconductor, according to certain exemplary aspects of the present disclosure, with the respectively-shown sets corresponding to a bottom-gate top-contact stretchable transistor with a fluorinated film as the semiconductor (FIG. 9A) during single stretching, and (FIG. 9B) after multiple stretching-releasing cycles at 50% strain.

While various embodiments discussed herein are amenable to modifications and alternative forms, aspects thereof have been shown by way of example in the drawings and will be described in detail. It should be understood, however, that the intention is not to limit the disclosure to the particular embodiments described. On the contrary, the intention is to cover all modifications, equivalents, and alternatives falling within the scope of the disclosure including aspects defined in the claims. In addition, the term “example” as used throughout this application is only by way of illustration, and not limitation.

### DETAILED DESCRIPTION

Aspects of the present disclosure are believed to be applicable to a variety of different types of apparatuses, systems and methods involving devices characterized at least in part by fluorinated molecules or a fluorinated layer covalently attached to a surface region corresponding to polymer material, such as a polymer semiconductor (PSC) film or stretchable encapsulation material (e.g., rubber). In the case of the surface region being a stretchable composite film, the film is characterized in that at least a portion of the polymer material is densified through the process of covalently attaching fluorination molecules. As a specific example, the present disclosure is directed to an electronic device (e.g., the device itself or directed to use and/or fabrication of the device) which includes a surface region, in the form of a layer or film, of the electronic device; and a fluorinated layer covalently attached to the surface region to enhance performance of the surface region. The performance is enhanced in terms of one or more parameters, said one or more parameters including or characterizing: operational stability of the surface region, or a manner of degree to which an electronic device is protected by the surface region. For example the operational stability of the electronic device may be associated with the surface region including or corresponding to a PSC film, and encapsulation performance associated with the surface region may include or correspond to a stretchable material protecting the electronic device. While the present disclosure is not necessarily limited to such aspects, an understanding of specific examples in the following description may be understood from discussion in such specific contexts.

Accordingly, in the following description various specific details are set forth to describe specific examples presented herein. It should be apparent to one skilled in the art, however, that one or more other examples and/or variations of these examples may be practiced without all the specific details given below. In other instances, well known features have not been described in detail so as not to obscure the description of the examples herein. For ease of illustration, the same connotation and/or reference numerals may be used in different diagrams to refer to the same elements or additional instances of the same element. Also, although aspects and features may in some cases be described in individual figures, it will be appreciated that features from one figure or embodiment can be combined with features of another figure or embodiment even though the combination is not explicitly shown or explicitly described as a combination.

Exemplary aspects of the present disclosure are related to highly stable and stretchable polymer electronics obtained through fluorinated layer encapsulation. According to certain aspects, example embodiments relate to a molecular engineering strategy to achieve highly stable PSC film in organic field-effect transistors (OFETs) enabling long-term use in harsh environments. According to specific examples of the present disclosure, one type of exemplary approach for providing (e.g., manufacturing) example structures involves two steps: (1) fixing morphology and introducing surface reactive sites simultaneously, and (2) covalently grafting chains onto PSC film through surface functionalization, which act as a protective layer against the diffusion of water or other environmental species (in certain of these examples, the chains are perfluorinated chains). Fluorinated surface functionalization or hydrophobic surface functionalization (can be with non-fluorinated molecules) are commonly used to create a superhydrophobic self-cleaning surface, non-sticking surface or anti-fouling surface (in this context, “fixed morphology” refers to occurrence of a cross linking reaction, either spontaneously through covalent or non-covalent bonding or by photo-initiation or thermal initiation, so that the morphology of the resulting film is stable in that it does not change easily with temperature, over time or is not readily dissolved away by solvents).

The strategy in such examples (e.g., using a fluorinated-molecular protective layer or FMPL) enables a highly stable PSC in OFETs over an extended period under various environments (including air, water/biofluids and sunlight), while simultaneously achieving good mechanical and improved electronic properties. Also, this strategy can be implemented into biosensors, organic light-emitting diodes and organic photovoltaics, allowing functional circuits with prolonged operation lifetimes (e.g., with receptors of bio-sensors attached directly onto stretchable polymer semiconductors of the sensors for chemical and biological sensing applications). Furthermore, this methodology and/or provided structure can be employed as a platform technology of general surface modifications. Besides perfluorinated chains, additional functional molecules can potentially be attached to expand the functionalities of polymeric electronic materials for more advanced applications.

Other example embodiments according to the present disclosure involve one or more electronic devices, including organic field-effect transistor (OFET), biosensors, organic light-emitting diode (OLED), organic photovoltaics (OPV) and organic electrochemical transistor (OECT). For example, these types of devices can benefit various wearable and implantable applications, wherein the device is in direct contact with physiological environment including, for example, water and/or biofluids. These example embodiments include wearable sensors for health monitoring, neural probes for brain-machine interface, biomedical prostheses and flexible displays. The covalently attached layer is stable and insensitive to mechanical deformation. Therefore, these aspects of the present disclosure are advantageous for soft, flexible and stretchable electronics, without the concern of interfacial delamination.

In more-specific example embodiments, aspects thereof are demonstrated as being substantial and significant improvements over previous approaches such as those described hereinabove. Compared to the commonly used encapsulation approaches, surface fluorination of charge transporting layer is especially advantageous to ensure long-term robustness of stretchable electronic devices. The covalently attached layer is insensitive to mechanical deformation, excluding the possible interfacial delamination artefacts inside encapsulated electronic devices due to modulus mismatch, and furthermore, in certain embodiments types of such a layer are used to eliminate selection constraints of encapsulation materials so as to meet stretchability requirements of specific applications. In connection with experimental efforts involving more-specific embodiments, the protection effect of fluorinated layer for transistors outperformed various stretchable polymer encapsulants, with constant bias stressing applied in air.

Consistent with the above aspects, such a manufactured device or method of such manufacture may involve aspects presented and claimed in U.S. Provisional Application Ser. No. 63/389,304 filed on Jul. 14, 2022 with figures and an Appendix, to which priority is claimed. To the extent permitted, such subject matter is incorporated by reference in its entirety generally and to the extent that further aspects and examples (such as experimental and/or more-detailed embodiments and aspects of its supplemental figures) may be useful to supplement and/or clarify.

According to certain more specific examples, the present disclosure is directed to a method and alternatively, a device manufactured from the method involving a semiconductive structure or device having a semiconductor: wherein the PSC film and the fluorinated layer are cooperatively configured as part of a composite semiconductor film of the semiconductor; wherein a rubber matrix phase is in a crosslinked composite semiconductor film, and the rubber matrix phase in a crosslinked composite semiconductor film includes the PSC film and the fluorinated layer being cooperatively configured to facilitate stability of the PSC film; and/or which includes an organic-field-effect transistor (OFET) wherein the PSC film, including the covalently-attached fluorinated layer, is as part of a composite semiconductor film of the OFET.

In certain other examples which may also build on the above-discussed aspects relating to one or more of the above types of apparatuses: the PSC film and the fluorinated layer are cooperatively configured as part of a composite semiconductor film of an organic-field-effect transistor (OFET) characterized by a charge carrier mobility that is maintainable at or above ˜1 cm²·V⁻¹·s⁻¹; the PSC film includes a crosslinked composite semiconductor portion, and further including covalently-grafted perfluorinated chains attached on the crosslinked composite semiconductor portion; and/or the PSC film, with the fluorinated layer covalently attached to the PSC film, and characterized in that the PSC film maintains substantially the same level of stretchability and charge transport mobility after N stretching-releasing cycles under at least 50% strain, wherein N is an integer in a range from 2 to 1000.

In a more specific aspect, the above type of structure or method is characterized in that: non-conjugated C═C bonds are used as reactive sites on the PSC film and a PSC is crosslinked with perfluorophenyl azide end-capped polybutadiene; the PSC film and the fluorinated layer are cooperatively configured as part of a composite semiconductor film having conjugated polymer interpenetrating with a crosslinked rubber matrix or having a rubber matrix phase in a crosslinked composite semiconductor film; and non-conjugated C═C bonds are introduced (during a method of manufacturing the PSC film) as reactive sites on the PSC film and subsequent surface fluorination is performed by initiating a thiol-ene reaction between the non-conjugated C═C bonds and perfluorodecanethiol (PFDT) via UV light.

In certain of these examples, the PSC film and the fluorinated layer are cooperatively configured as part of a composite semiconductor film of an organic-field-effect transistor (OFET) type semiconductor with the OFET being characterized by a charge carrier mobility that is maintainable at or above ˜1 cm2·V-1·s-1, and such film is stable over one or more harsh environments inclusive but not necessarily limited to those disclosed herein.

Also according to the present disclosure, using such manufacture-related methodology, various semiconductor structures and/or devices may be characterized as including (or manifesting) attributes of one or more aspects of such methodology such as through imaging of the structure and/or structural properties (and in some instances also operational properties) uniquely corresponding to such attributes. Examples of such imaging and properties are disclosed in connection with various experimental efforts described or illustrated in connection with the present disclosure. While such experimental examples (e.g., as disclosed herein) have demonstrated exemplary aspects and attributes of semiconductor structures useful for certain types of semiconductor devices, it should be appreciated that such semiconductor devices and circuits are not intended to be limiting as such aspects and attributes are applicable to other types of devices and structures including but not limited to one or a combination of: biosensors, organic light-emitting diodes, and organic photovoltaics.

Before turning to the drawing to be discussed in detail below, it is noted that each of the above examples are presented in part to illustrate aspects of the present disclosure, as might be recognized by the foregoing discussion which is primarily directed to certain experimental and/or more-detailed aspects and embodiments according to the present disclosure.

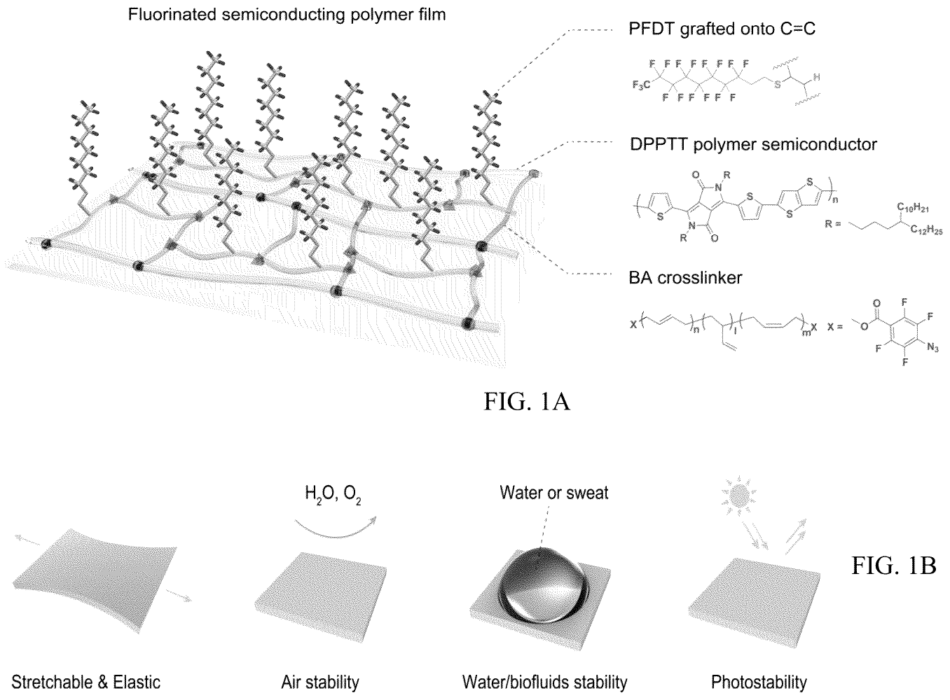

FIGS. 1A and 1B illustrate example aspects of achieving long-term environmental stability in a stretchable polymer semiconductor film through surface fluorination according to certain example embodiments. More specifically, FIG. 1A illustrates a fluorinated semiconductor film, where PFDT is covalently grafted onto the non-conjugated C═C of the rubber matrix phase in a crosslinked composite semiconductor film, forming a uniform layer. In FIG. 1B, the fluorinated film is shown as being stretchable and elastic, while exhibiting highly stable charge transport characteristics in various harsh environmental conditions over a long period of time. The conditions include storing in humid air, soaking in water or artificial sweat, and irradiating with sunlight.

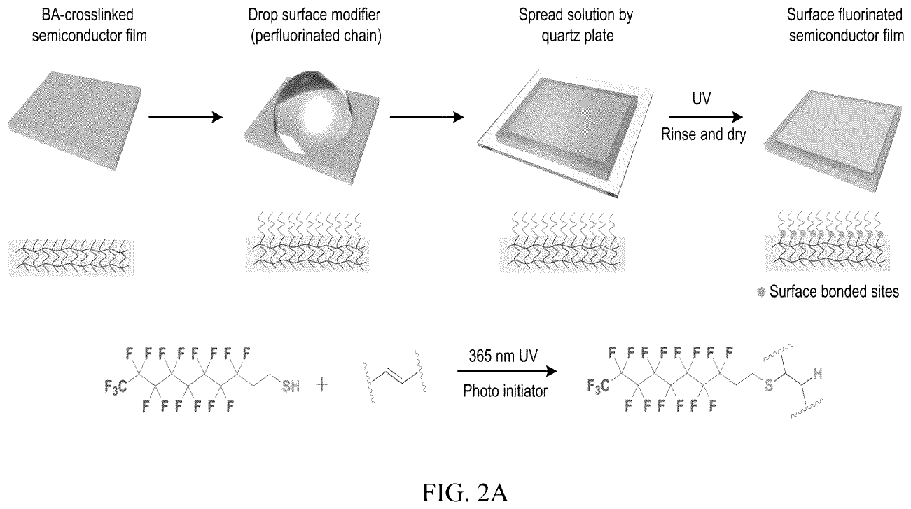

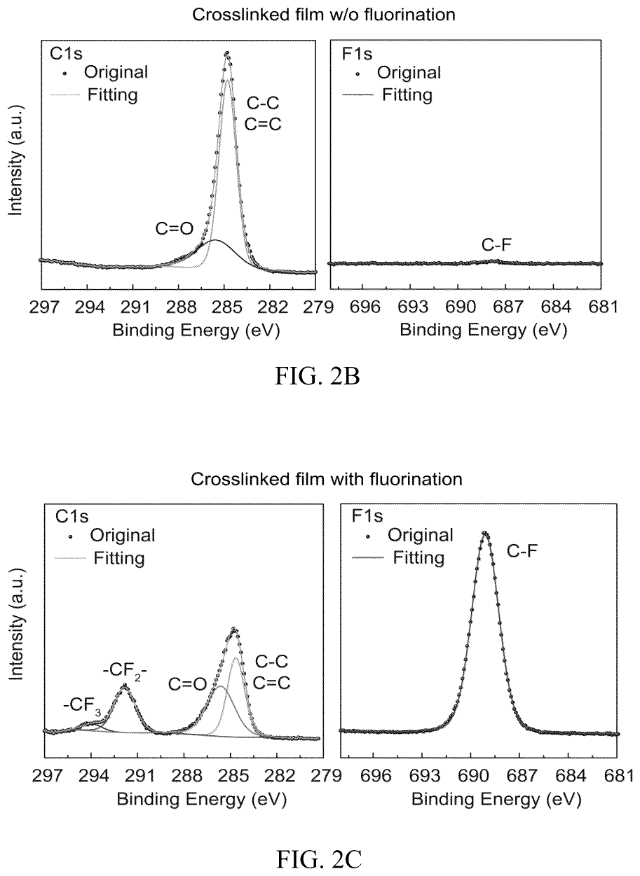

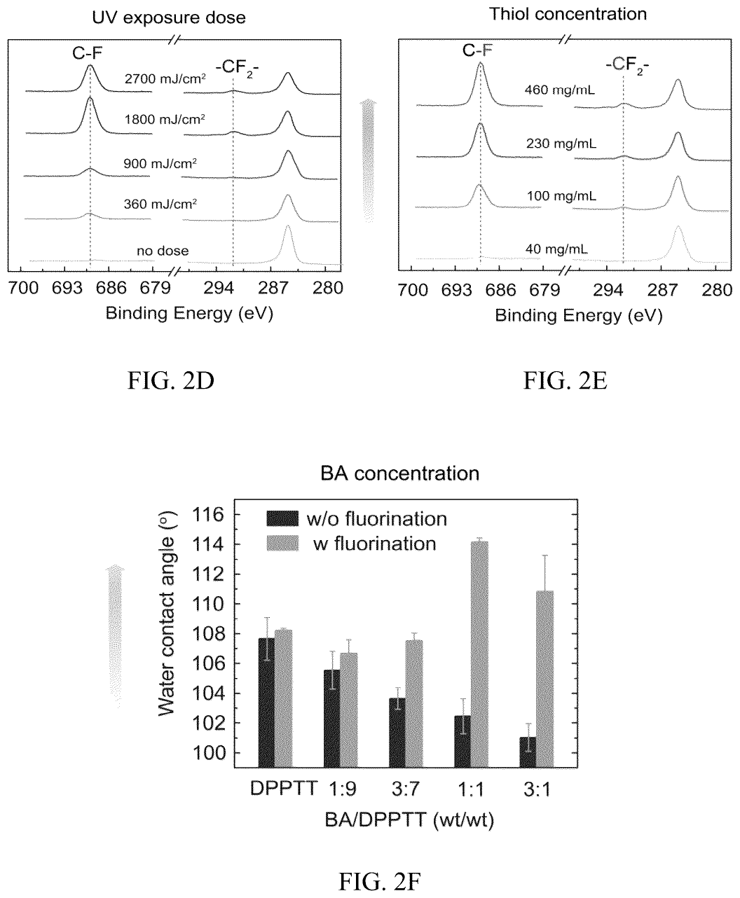

FIGS. 2A-2F illustrate example aspects of surface fluorination on crosslinked composite semiconductor films according to further embodiments of the present disclosure. FIG. 2A shows a fabrication process of PSC surface fluorination in connection with specific example embodiments using a (e.g., donor-acceptor) conjugated polymer (e.g., poly-thieno[3,2-b]thiophene-diketopyrrolopyrrole (sometime generally as DPPTT) (Mn: 72 kg/mol, PDI: 3.0), which serves as a model semiconductor for the exemplary approaches and film structures disclosed in connection with the present disclosure. The covalent bonds between a crosslinked semiconductor film and fluorinated layer are constructed through thiol-ene reaction under 365 nm UV-light for 10 min with photo initiator.

As shown in FIG. 2A, the procedure is as follows. First DPPTT is crosslinked with BA in 1:1 weight ratio. Based on previous studies demonstrating that BA distributes uniformly across film surface and thickness, it is estimated that there are about 140 reactive sites (non-conjugated C═C groups on BA) for every 10 DPPTT repeating units located on the crosslinked film surface. The abundance and accessibility of the reactive sites serve as the key premise of efficiently grafting functional molecules on the crosslinked semiconductor films. The solution with PFDT and photo initiator is dropped onto crosslinked film surfaces, followed by placing a quartz plate on top to spread the solution. Subsequently, UV-light (at 365 nm) is applied to initiate the thiol-ene reaction for PFDT surface attachment. The low-energy UV-light dosage does not damage the semiconductor films. A quartz plate can largely reduce the thickness of F-solution layer, thus shortening UV-light pathway and increasing reaction efficiency. After UV-light curing for ˜10 min in air, the semiconductor film is then washed with fluorinated solvent, followed by post-annealing to fully remove the residue species (and to realize the functionalized semiconductor film (“fluorinated film”).

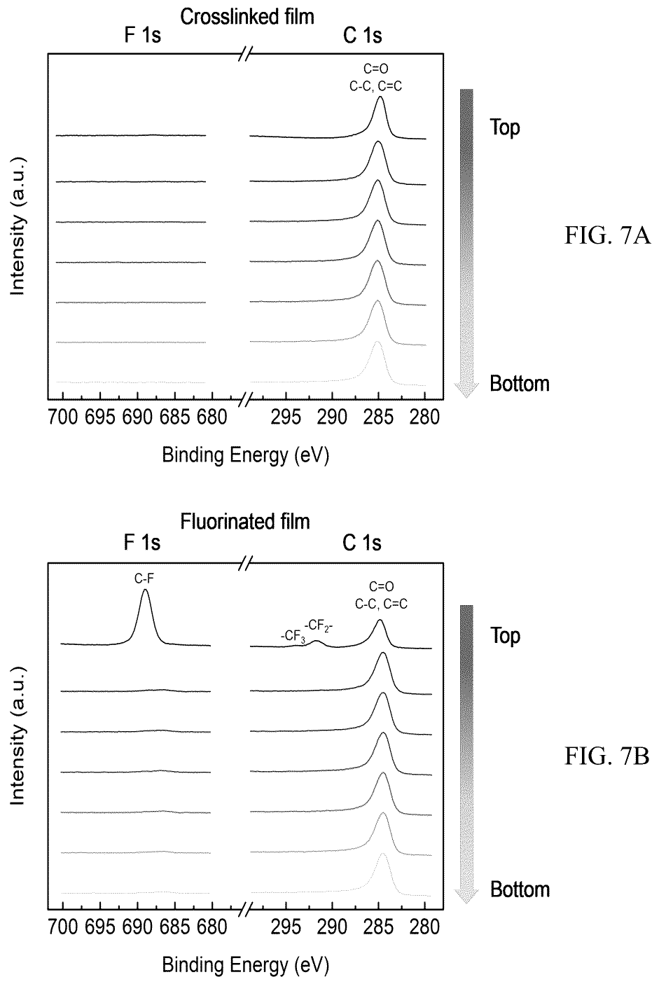

In such experimentation, X-ray photoelectron spectroscopy (XPS) was initially performed to investigate the surface chemical composition of the crosslinked films before and after fluorination. For the fluorinated films, the C 1s spectrum showed the appearance of binding energy peaks at 294 and 292 eV corresponding to —CF3 and —CF2- of PFDT. The F 1s spectrum exhibited a peak at 689 eV, which was assigned to C—F, supporting the successful grafting of F-thiol (FIGS. 2B and 2C). Depth profiles indicated that PFDT was only present on the top surface of the film, with no vertical diffusion (see FIGS. 7A and 7B herein).

Furthermore, for these specific experiments it was confirmed (and/or discovered) that PFDT is able to be physically absorbed onto a semiconductor film with the presence of non-conjugated C═C from BA as reactive sites (see, e.g., supplementary FIG. S3 of the above-referenced U.S. Provisional application and Table S2 herein). Due to the covalent attachment, the fluorinated layer is highly stable on a semiconductor film over long-term usage.

‘Overall, these experiments demonstrated that the developed surface fluorination approach is efficient and can be achieved under ambient conditions in short time scale and thus eliminated demanding processing requirements. The experiments also show that the degree of surface fluorination is highly tunable through molecular exposure of PFDT to semiconductor film and the amount of surface reactive sites. With UV-light exposure dose, thiol solution and BA concentration increasing, both the relative intensity of PFDT characteristic XPS peaks and water contact angle increased (see, e.g., FIG. 2D-2F and Supplementary FIGS. S4-S6 of the above-referenced U.S. Provisional application), indicating higher fluorination degree. The XPS intensities and contact angles reached a maximum after UV-light exposure of 1800 mJ·cm-2, thiol concentration of 230 mg/ml and BA/DPPTT weight ratio of 1:1, indicating saturated surface fluorination. These conditions were adopted in stability studies consistent with the experimental efforts disclosed herein.

Besides DPPTT, this surface fluorination method is versatile for various high-performance polymer semiconductors. The approach saves synthetic efforts without the need to modify conjugated polymer molecular structure (backbone or side chain). In these experiments, the fluorinated semiconductor films exhibited an increased water contact angle, indicating successful grafting (see, e.g., Supplementary FIG. S7 of the above-referenced U.S. Provisional application).

FIGS. 2B and 2C include XPS spectra of a crosslinked semiconductor film before surface fluorination (FIG. 2B) and after surface fluorination (FIG. 2C), with film thickness for both being around 35 nm. In certain experimentation according to the present disclosure, assignment of C 1s and F 1s emission lines to the molecular structure of F-thiol indicated successful surface fluorination. FIGS. 2D and 2E include XPS spectra of fluorinated semiconductor films with different UV exposure dose (FIG. 2D) and concentration of F-thiol solution (FIG. 2E). In FIG. 2F, water contact angles of crosslinked semiconductor films are shown as manifesting different concentration of perfluorophenyl azide end-capped polybutadiene (BA) before and after surface fluorination.

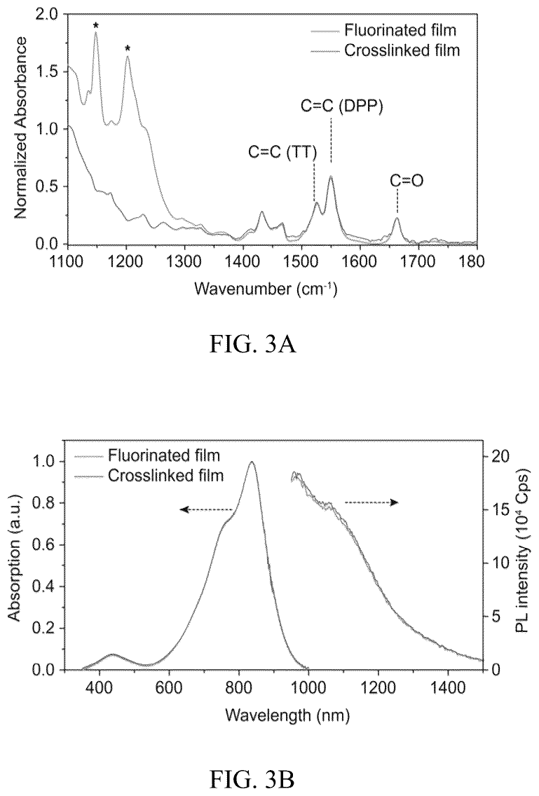

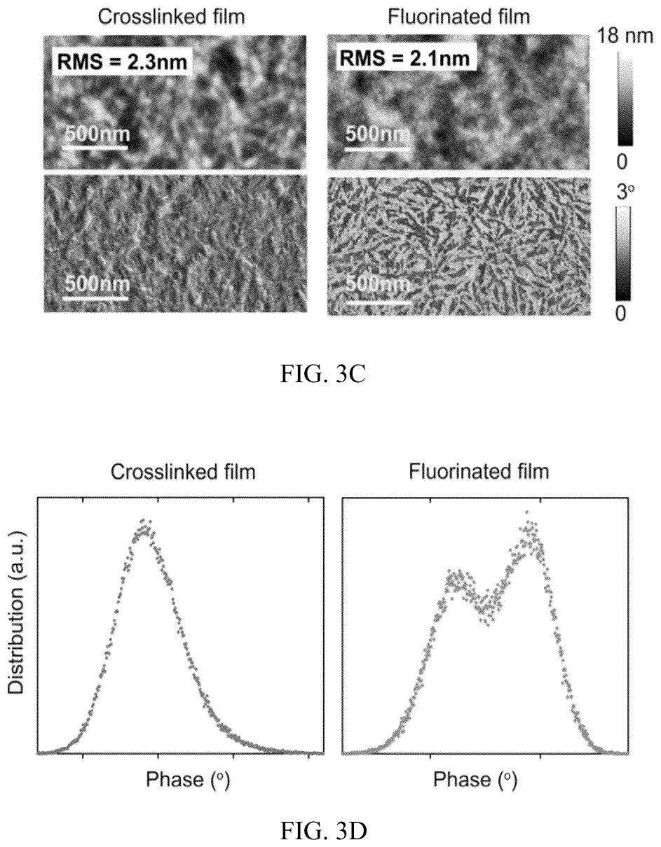

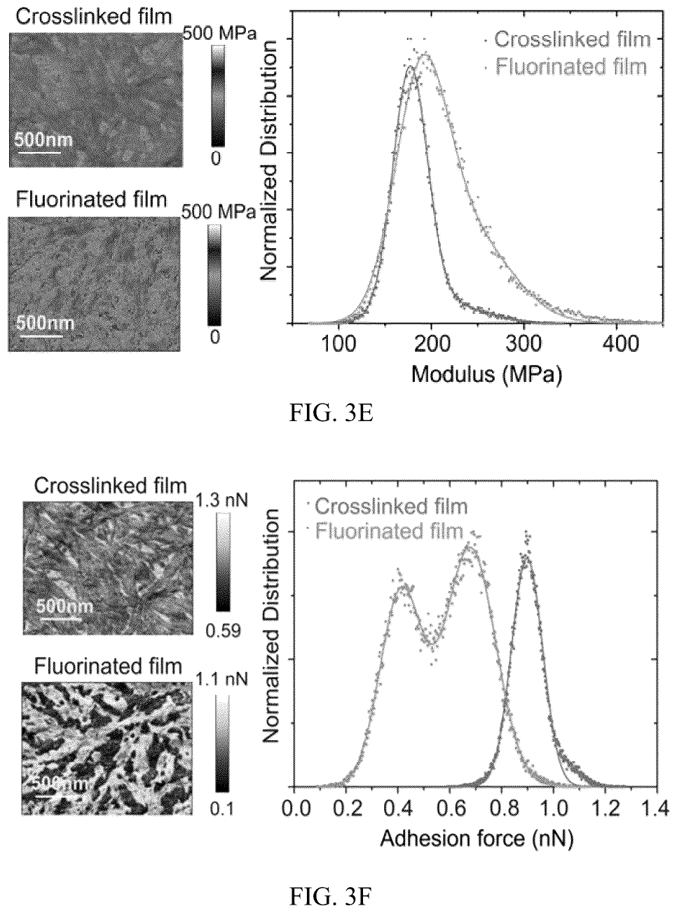

FIGS. 3A-3F illustrate example aspects of morphological and mechanical properties characterizations according to example embodiments of the present disclosure, with FIG. 3A showing FTIR transmission spectrum of fluorinated and crosslinked films (annotated peaks with asterisk (*) representing the characteristic C—F stretching peaks from F-thiol). In FIG. 3B, normalized UV-vis absorption and PL spectra are illustrated for films. In FIGS. 3C and 3D, AFM height (top of FIG. 3C), phase-images (bottom of FIG. 3C) and phase distribution diagrams (FIG. 3D) of crosslinked/fluorinated films are shown. FIGS. 3E and 3F show normalized distribution of modulus (FIG. 3E) and adhesion force (FIG. 3F) for semiconductor films obtained via nanomechanical imaging. In these specific experiments, the force modulation measurements were performed at a setpoint of 500 pN with a peak force frequency of 2 kHz and amplitude of 150 nm.

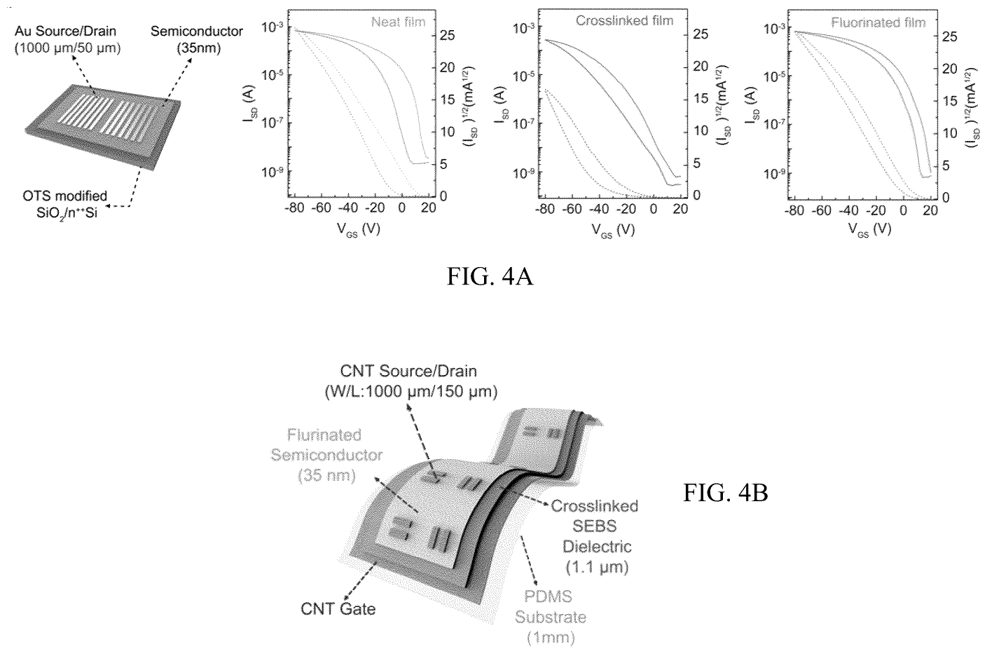

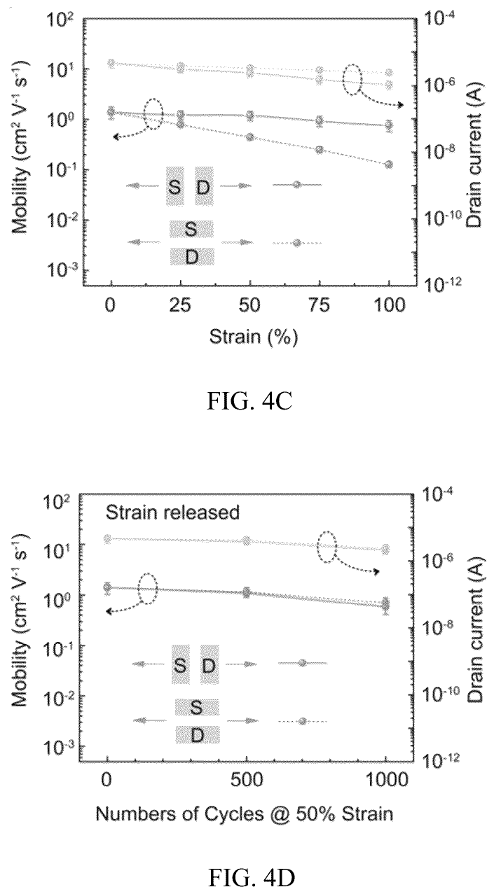

FIGS. 4A-4D illustrates example aspects of electrical performance of transistors according to embodiments of the present disclosure. FIG. 4A shows device structure and representative transfer curves of bottom-gate top-contact rigid transistors, using different semiconductors (neat, crosslinked or fluorinated), highly-doped Si as a gate electrode, Au as source/drain electrodes (W=1000 μm, L=50 μm) and octadecyltrimethoxysilane (OTS)-modified SiO2 (300 nm) as dielectrics (solid lines: drain current; dash lines: square root of the drain current). FIG. 4B shows device structure of a bottom-gate top-contact stretchable transistor with fluorinated semiconductor, carbon nanotube (CNT) as gate and source/drain electrodes (W=1000 μm, L=150 μm), crosslinked SEBS (1.1 μm) as dielectrics, and PDMS (1 mm) as stretchable substrate. FIGS. 4C and 4D show evolution in transistor drain current and extracted mobility for a fluorinated semiconductor film at different strains during single stretching (FIG. 4C) and after multiple stretching-releasing cycles at 50% strain under strain released state (FIG. 4D), with charge transport parallel (solid lines) and perpendicular (dash lines) to stretching direction.

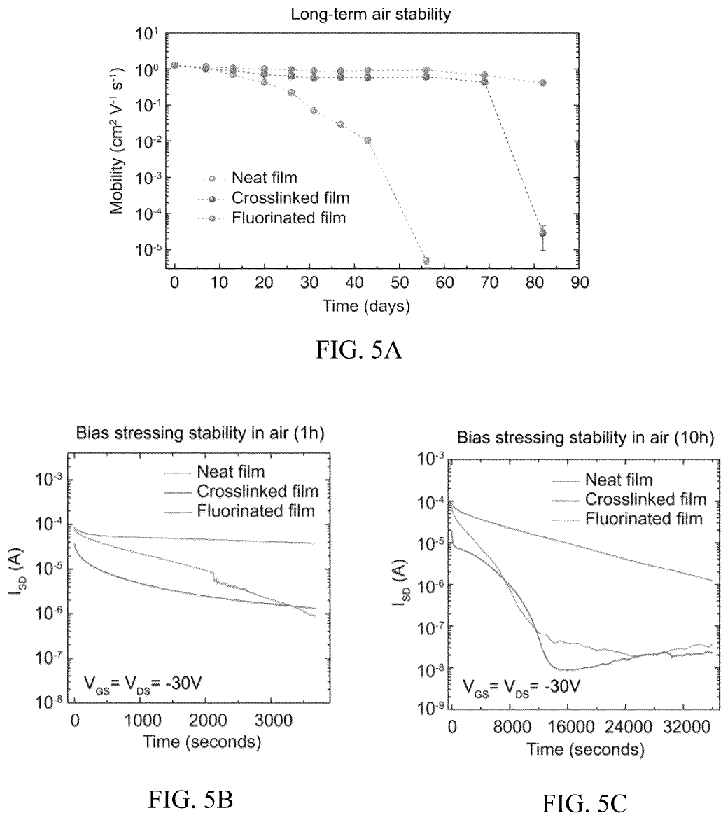

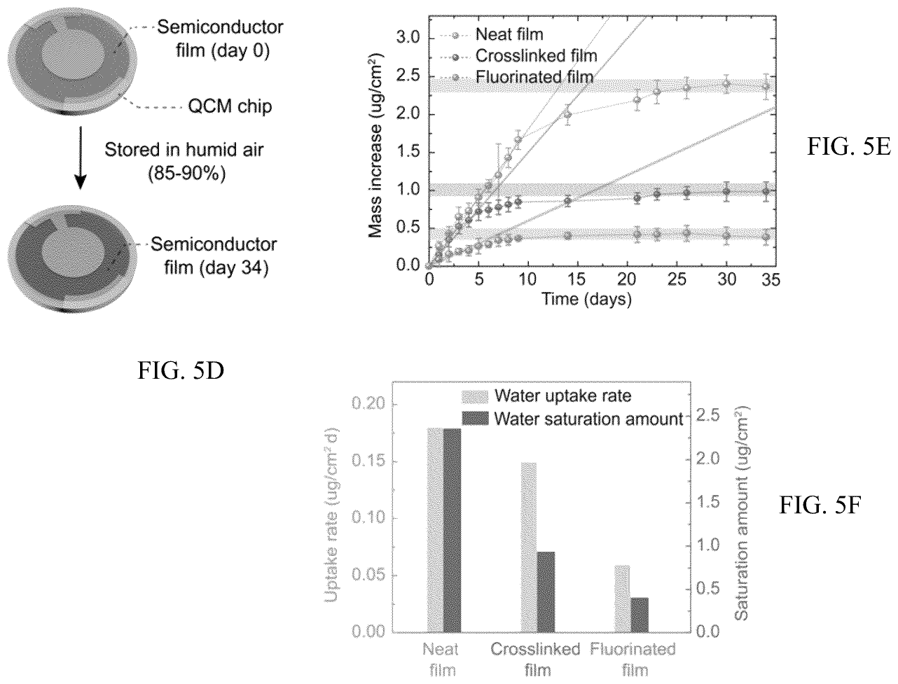

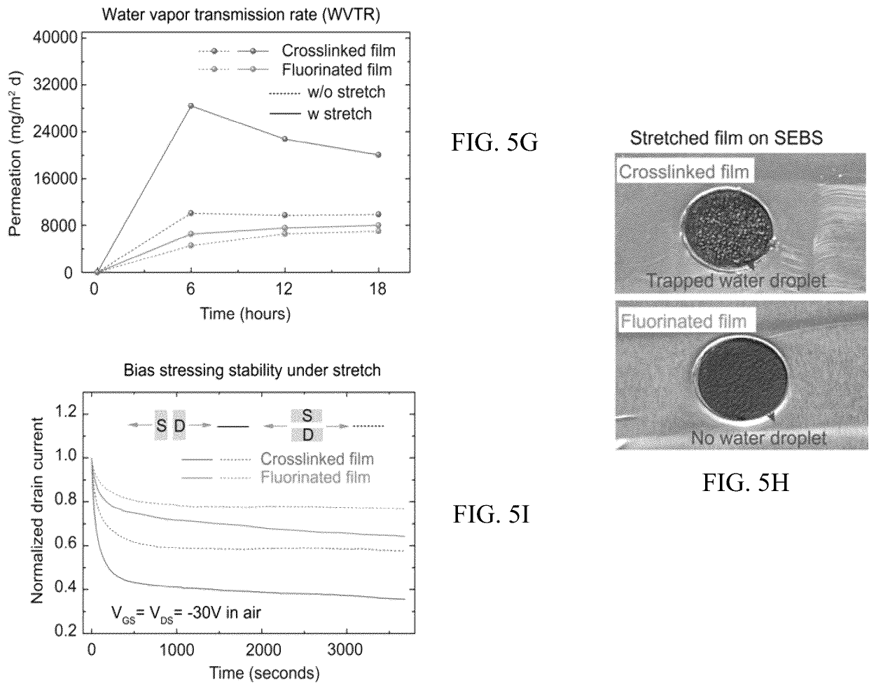

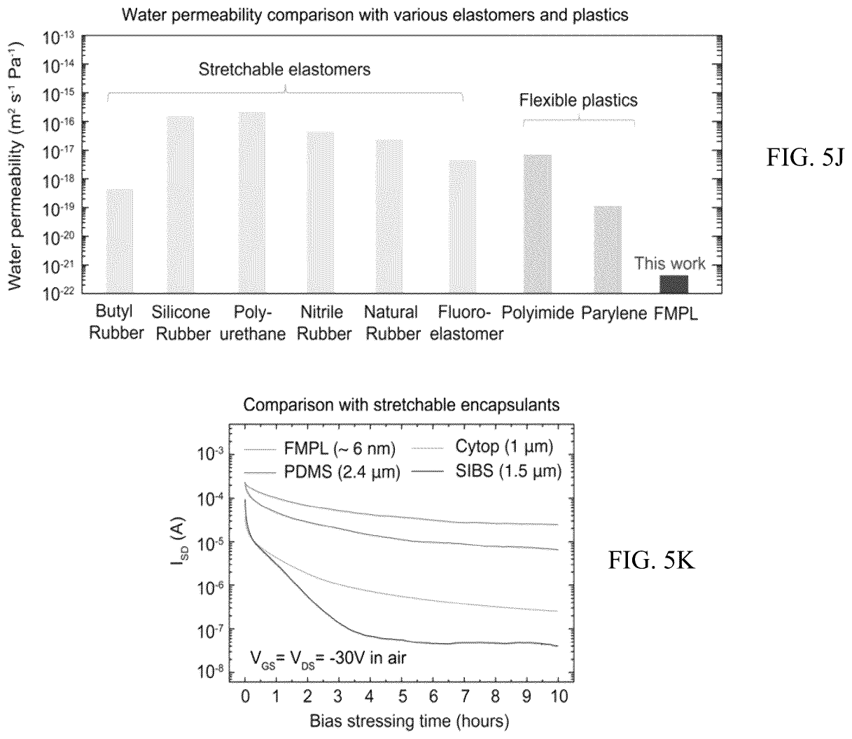

FIGS. 5A-5F illustrate example aspects of operational stability in air according to example embodiments also consistent with such experiments of the present disclosure. FIG. 5A shows time evolution of the mobilities of the semiconductor films stored in air (humidity: 85%-90/o, and in other examples, the stability was established in relative humidity at levels of anywhere of greater than twenty percent). The mobility was extracted from the transfer curve of a bottom-gate top-contact transistor. Each data point was obtained by averaging more than eight devices. FIGS. 5B and 5C show bias stressing stability of semiconductor films under the constant application of VGS=VDS=−30 V in air for 1 h (FIG. 5B) and for 10 h (FIG. 5C). FIG. 5D is a schematic illustration showing coated QCM chips to monitor mass change of semiconductor films over time in humid air, corresponding to water absorption (in this experimentation, the semiconductor film was spin-coated on QCM chip). FIG. 5E illustrates mass uptake of semiconductor films over 34 days. FIG. 5F shows extracted water saturation amount and initial uptake rates (linear regime) for such semiconductor films.

FIGS. 5G-5K illustrate further example aspects of operational stability of electronic devices (with such films or surface regions) in air according to specific example embodiments which are also consistent with experiments of the present disclosure. FIG. 5G shows water vapour transmission rate (WVTR) measurements of such films (35 nm thick) supported on a SEBS (Styrene-ethylene-butylene-styrene) substrate having a thickness of 1 mm. More particularly, FIG. 5G shows time evolution of water permeation of different semiconductor films with or without stretching, and FIG. 5H shows images of stretched crosslinked film (top) and fluorinated film (bottom) under 50% strain after WVTR measurement. FIG. 5I shows bias stressing stability of stretchable transistors with different semiconductor films (FIG. 4D) at 50% strain under the constant application of VGS=VDS=−30 V in air for 1 h, with charge transport parallel (solid lines) and perpendicular (dash lines) to stretching direction. FIG. 5J shows water permeability comparison of FMPL with various stretchable elastomers and flexible plastics as previously characterized (see Le Floch, P., Meixuanzi, S., Tang, J., Liu, J. & Suo, Z. Stretchable Seal. ACS Appl. Mater. Interfaces 10, 27333-27343 (2018)). FIG. 5K shows a comparison of the protection effect of FMPL on a crosslinked semiconductor film with other stretchable polymer encapsulants. The transistors (FIG. 4C) were under the constant bias of VGS=VDS=−30 V in air for 1 h, and the polymer encapsulants were directly spin-coated on the transistors as protection layer with PDMS (2.4 μm thick), Cytop (1 μm thick), SIBS (1.5 μm thick).

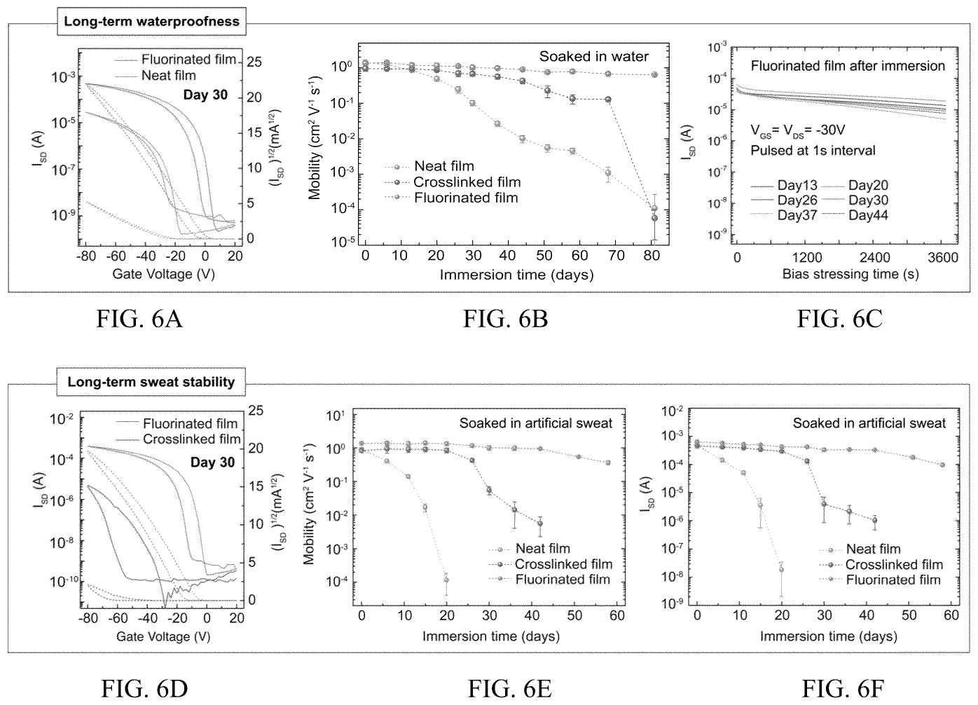

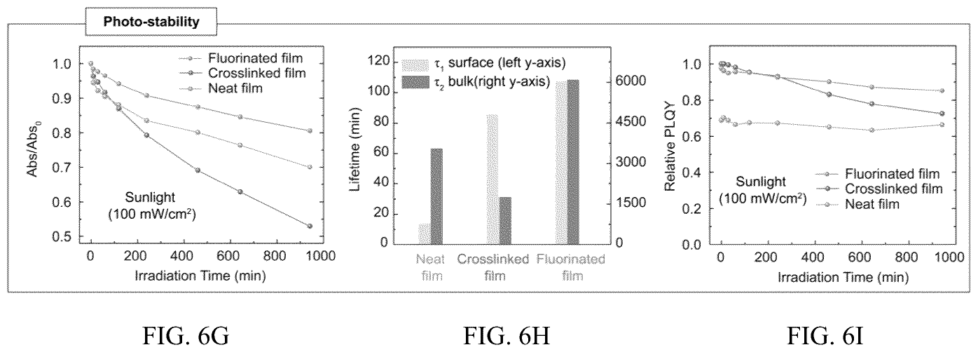

FIGS. 6A-6I illustrate example aspects of long-term water, sweat and photochemical stability according to embodiments. FIG. 6A, representative transfer curves of a fluorinated film and a neat film are illustrated. The transistors were soaked in water for 30 days and took out for measurement in air. FIG. 6B shows time evolution of the mobilities of the semiconductor films immersed in water. The transistors were soaked in water, taken out for 1-hour bias stressing and transfer characteristics measurement in air on different days. The mobility was extracted from the transfer curve. In FIG. 6C shows bias stressing stability of a fluorinated semiconductor film according to the present disclosure after soaking in water for different days, under the application of VGS=VDS=−30V constantly in air for 1 hour (hr). FIG. 6D shows representative transfer curves of such a fluorinated film and a crosslinked film. The transistors were soaked in artificial sweat for 30 days and took out for measurement in air. FIGS. 6E and 6F show time evolution of the mobilities of different semiconductor films (FIG. 6E) and transistor drain current immersed in artificial sweat (FIG. 6F). FIG. 6G shows normalized UV-vis absorption changes of different semiconductor films with different amount of sunlight irradiation time. FIG. 6H shows the extracted lifetimes under sunlight, and FIG. 6I shows the changes of PLQY over sun irradiation time.

In certain specific example embodiments of the present disclosure, methods for manufacturing the PSC film included fixing the morphology and introducing non-conjugated C═C bonds as reactive sites accessible on film surface by crosslinking a PSC with perfluorophenyl azide end-capped polybutadiene (BA). Through this step, a composite semiconductor film with DPPTT-type of network interpenetrating with crosslinked rubber matrix was realized which, as DPPDTT (e.g., poly-thieno[3,2-b]thiophene-diketopyrrolopyrrole) is a high mobility p-type polymer, is suitable and important for OFET and sensing and photovoltaic applications. In one specific example, at least one of the following was performed: subsequent surface fluorination by initiating a thiol-ene reaction between the non-conjugated C═C bonds and perfluorodecanethiol (PFDT) via UV light; and crosslinking with perfluorophenyl azide end-capped polybutadiene.

Subsequent surface fluorination was conducted by initiating thiol-ene reaction between these non-conjugated C═C bonds and perfluorodecanethiol (PFDT) via UV light. As a result, a fluorinated layer was covalently attached onto the rubber matrix phase in a crosslinked composite semiconductor film (FIG. 1A). The approach is efficient, reliable and can be applied to various high-performance PSCs. More importantly, it was observed that the PSC environmental/operational stability was iteratively and significantly improved after these two steps. Enhanced electrical performances in OFETs were even observed after surface fluorination which results from decreased contact resistance with source/drain electrodes. The electrical characteristics of OFET using a surface-fluorinated semiconductor film remain stable either with or without bias stressing under harsh environmental conditions over extended period. Specifically, the extracted charge carrier mobility was well maintained at ˜1 cm2·V-1·s-1 even after storing in humid air for 8 weeks or after immersing in water and artificial sweat for ˜5-6 weeks. The underlying mechanism for the improved performance stems from the super-hydrophobicity of perfluorinated chains, which retard the absorption and penetration of water or biofluids into semiconductor film, as quantitatively evidenced by nanomechanical imaging via atomic force microscopy (AFM), quartz crystal microbalance (QCM) and surface plasmon resonance (SPR). Additionally, the fluorinated layer improved the photostability of a PSC film in air through deepening the HOMO (highest occupied molecular orbital) energy level, which underwent a much slower degradation under sunlight irradiation. Furthermore, the obtained fluorinated film was highly stretchable and elastic, while it exhibited a high mobility of ˜1.38 cm2·V-1·s-1. Applications and other embodiments of the present disclosure provide a platform technology for PSC surface functionalization and an approach for a molecular design to enable high stability in polymer electronics.

Also according to the present disclosure, discussion now turns to exemplary aspects concerning of morphology, mechanical and electrical properties. In connection with such experimentation the morphology of the fluorinated semiconductor films was characterized. DPPTT vibrational peaks which are fully preserved in FTIR transmission after surface fluorination, indicating minimal main chemical structure perturbation (FIG. 3A). Furthermore, the fluorinated film exhibited identical UV-vis absorption (FIG. 3B) and grazing-incidence X-ray diffraction as the crosslinked film, indicative of undisrupted semiconductor aggregation and crystalline packing. In addition, no photoluminescence (PL) quenching occurred after fluorination (FIG. 3B), indicating that a perfluorinated layer does not result in polaron formation in semiconductor film through molecular doping. The above characterizations indicate that PFDT only distributed on film surface, without changing the intrinsic chemical and aggregation properties of the “bulk” film.

Further, the surface morphology of the crosslinked and fluorinated films was investigated via AFM. As part of the present disclosure, it has been discovered that the roughness of the semiconductor film did not increase after surface fluorination (RMS of 2.1 nm, FIG. 3C). Interestingly and surprisingly as one of the important advancements concerning one aspect of the present disclosure, there was a much stronger phase difference in the fluorinated films compared to the crosslinked films, as shown by the distinct bimodal distribution diagram (FIG. 3D). The differences in the phase image can be explained through the increased local chemical contrast induced by attaching fluorinated molecules onto the crosslinked rubber phase in the composite film. The super-hydrophobicity of perfluorinated chains made the fluorinated phase interact differently with cantilever than the non-fluorinated phase. These fluorinated molecules are uniformly dispersed on film surface, as confirmed by the composition map obtained through pairing AFM with infrared spectroscopy (AFM-IR) and SEM-EDXS. Relating to permeability, surprisingly the liquid (e.g., water) permeability of the thin film or layer is multiple orders of magnitude lower than other known elastomers (e.g., compared to elastomers discussed in connection with the above-reference U.S. Provisional application).

Nanomechanical imaging was also performed on the semiconductor films. In the modulus mapping, it was observed that the average modulus of the fluorinated films was higher than that of the crosslinked films, indicating that the material possessed denser top surface through the fluorination procedure (FIG. 3E). Also, the fluorinated film exhibited much lower adhesion force than the crosslinked films, with a clear bimodal distribution corresponding to two phases of the semiconductor composite. The shift in adhesion forces was related to both the grafting of perfluorinated chains and the accompanied reduction of hydration layer on the film surface as in FIG. 3F.

In addition to mechanical characterization on the nanoscale level, bulk mechanical properties of different semiconductor films were investigated by transferring them onto a polystyrene-block-poly(ethylene-co-butylene)-block-polystyrene (SEBS) substrate. In these example experiments, both the crosslinked and fluorinated film can be stretched up to 100% strain without any visible cracks occurring under optical microscope. Additionally, after the strain was released, both films returned to original state without wrinkle formation. Therefore, surface fluorination of crosslinked semiconductor films does not influence its stretchability and elasticity. Furthermore, the water contact angle on both the crosslinked and fluorinated film did not change at different applied strains, maintaining around 101° and 1100, respectively. These water contact angles indicate that the covalently attached PFDT molecules pack densely on the semiconductor films, thus surface properties of a fluorinated film could be maintained even during stretching at 100% strain. Further characterized was the stretched fluorinated film under AFM—the fluorinated layer is quite stable and resilient to mechanical deformation.

Next were fabricated bottom-gate top-contact transistors to investigate the influence of surface fluorination process on semiconductor electrical performance (FIG. 4A). The fluorinated films exhibited higher drain current and lower threshold voltage compared to the crosslinked films without undesirable increase in off-current. The higher drain current and lower threshold voltage are a result from the reduced contact resistance (from 130.1 kΩ·cm to 7.5 kΩ·cm) with the Au electrodes after introducing the perfluorinated layer on the semiconductor film surface (FIG. 4A). The contact resistance issue was previously addressed by using a MoO3 interlayer. Notably, UV-light exposure in air for 10 min did not degrade the semiconductor charge transport, indicating that the surface fluorination approach is non-invasive. It was also confirmed that the immersion of the crosslinked or neat film in PFDT solution did not result in an improvement in the contact resistance. Transistor performance improvement could only be observed through covalent attachment of the PFDT molecules on the PSC film surface, hence excluding the possibility of molecular doping in the thin films. It was hypothesized that the reduced contact resistance originates from the mobile charge accumulation and trap-healing effect of fluorinated molecules on the semiconductor surface, along with work function modulation of organic interlayer at the semiconductor/metal interface.

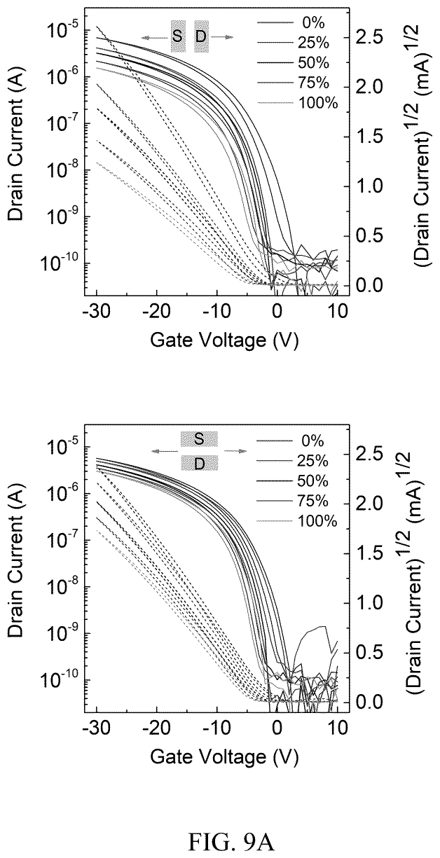

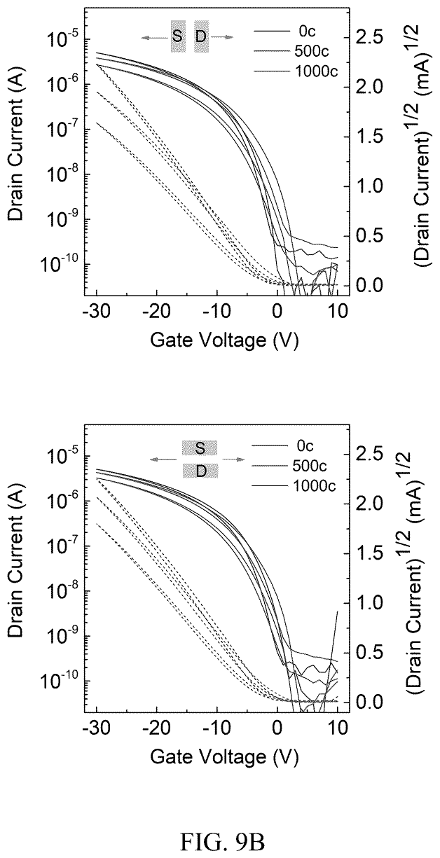

Fabrication of fully stretchable transistor included characterizing the electrical performance evolution of fluorinated semiconductor film under mechanical deformation (FIG. 4B). Without strain applied, the stretchable transistor with fluorinated film exhibited a high charge carrier mobility of 1.38 cm2·V-1·s-1, along with a higher drain current and lower threshold voltage than the crosslinked film. This indicates that fluorinated layer can reduce contact resistance of PSC film with different electrodes (CNT and Au). The mobility of the fluorinated films was well maintained during a single stretch cycle until 100% strain, and after 1000 stretching-releasing cycles under 50% strain (FIGS. 4C-4D, FIGS. 9A-9B). Compared to commonly-used encapsulation approaches, in these examples surface fluorination of charge transporting layer is especially advantageous to ensure long-term robustness of stretchable electronic devices. The covalently attached layer is insensitive to mechanical deformation, excluding the possible interfacial delamination artefacts inside encapsulated electronic devices due to modulus mismatch. Furthermore, it eliminates selection constraints of encapsulation materials to meet stretchability requirements.

While many experimental examples of the present disclosure involve use of an encapsulation material which is a blend of a polymer semiconductor and an elastic matrix, moieties therein can be subsequently modified through any of various surface grafting chemistries (e.g., as in such experimental examples, using thiol-ene reactions and other reactions such as an azide-alkyne chemistry, a bezophenone grading chemistry, and an azide functionalization chemistry). Also, the polymer semiconductor material can be replaced with another densely packed conjugated or non-conjugated polymer(s). Additionally, inorganic fillers can be added to further increase the moisture and oxygen blocking properties, such as graphene oxide, boron nitride, titanium oxide, silicon oxide, and silicon nitride.

Also, surface functionalization can be with per fluorinated alkane, partially fluorinated alkane or long-chain non-fluorinated alkane (C8 or longer), and the functionalization may be with linear or branched molecules.

After confirming the fluorinated semiconductor film has the desired mechanical/electrical properties for stretchable electronic devices applications, next investigated was operational stability in air and if the PSC stability in OFETs can be improved through exemplary surface-fluorination approaches according to the present disclosure. The transistor stability is related to the intrinsic energy levels (HOMO and LUMO) of the semiconductor layer, and the trap density at dielectric surface and device architecture. Bottom-gate top-contact transistors were fabricated as shown in FIG. 4A, where the semiconductor film in the charge transporting channel was directly exposed to air. Bottom-gate devices are generally less ambient-stable than top-gate ones, because they lacked the encapsulation from the top dielectric layer. The transistor stability can also potentially be further increased by fine tuning the device architecture and materials selection.

First evaluated were the electrical characteristics of these transistors stored in air (humidity: ˜85-90%) in defined time intervals. The neat film continuously degraded over time. After one month, the charge carrier mobility decreased from 1.2 cm2·V-1·s-1 to 0.07 cm2·V-1·s-1, while exhibiting nearly two orders of magnitude decrease in drain current. It was observed that the stability of the crosslinked film lasted longer than neat film, in which it exhibited a slower decrease of mobility from 1.3 cm2·V-1·s-1 to 0.6 cm2·V-1·s-1 after one month storage (FIG. 5A). However, this surface fluorination approach was able to further improve the semiconductor stability in humid air. The fluorinated film maintained a high mobility of 1 cm2·V-1·s-1 and a drain current of 0.34 mA even after 56 days.

Operational stability of OFETs is often required for numerous specific long-term applications, such as voltage-driven display technology. Therefore, next performed was bias stressing measurements on these transistors in air. It was found that the fluorinated film underwent a much slower drain current decay over time compared to both neat and crosslinked film. It was observed that after stressing the transistors at constant bias of VDS=VGS=−30 V for 1 hour, the fluorinated film retained 44% of the initial IDS, while the neat and crosslinked films were able to only retain 1% and 4% of the initial IDS, respectively (FIG. 5B). Furthermore, both neat and crosslinked film exhibited over three orders of magnitude decrease in IDS after 4 hours and remained at a low value of ˜0.01 μA upon further increasing the bias stressing time. In c, the fluorinated film was able to still retain ˜14% of the initial drain current after 4-hour stressing, exhibiting a less than one order of magnitude decrease. Even after stressing in air for 10 hours, the fluorinated film was able to still maintain a high current value of 1.26 μA, as shown in FIG. 5C.

In connection with the present disclosure and leading to certain of the experimentation efforts disclosed herein, it was hypothesized that this remarkable improvement in PSC environmental and operational stability originated from the retarded moisture diffusion due to the fluorinated layer. To verify this hypothesis of decreased water diffusivity, quartz crystal microbalance (QCM) was utilized to monitor mass changes of the different semiconductor films in humid air (FIGS. 5D and 5E). As compared to neat films, it was observed that the crosslinked films showed a slightly lower water uptake rate from 0.18 to 0.15 ug·cm-2·d-1. However, the saturation level decreased by more than two times from 2.35 to 0.93 ug·cm-2 (FIG. 5F). The changes in chemical composition through the introduction of the polybutadiene-based rubber matrix is a possible explanation for the lower saturation of the crosslinked films in comparison to the neat semiconductor films. In contrast, the perfluorinated layer acted as a water-diffusion barrier and exhibited a superior protection effect due to its superhydrophobicity. Compared to the crosslinked film, the fluorinated film exhibited a lower water uptake rate from 0.15 to 0.06 ug·cm-2·d-1. On the other hand, the water saturation amount was further reduced to 0.4 ug·cm2 (FIG. 5F), which can be related to an increase in film density during surface fluorination process as evidenced by the modulus increase observed via nanomechanical imaging (FIG. 3E).

Such experiments also demonstrated semiconductor stability in liquids such as water and artificial sweat, which is deemed important for semiconductor wearables such as wristbands, rings, eyewear, and other skin-proximal electronic devices (e.g., bio-sensors). In connection with such experiments showing superior water repellency of the perfluorinated layer, the protection effect on semiconductor film under harsher environmental conditions was investigated over extended durations. In certain examples, the transistors were immersed into water, and were then removed for 1-hour bias stressing and transfer characteristics measurement in air on different days. It was observed that the neat films suffered dramatic decay over time, e.g., the mobility decreased from 1.4 cm2·V-1·s-1 to 0.1 cm2·V-1·s-1 after one-month soaking. In contrast, the fluorinated film exhibited a maintained high mobility of over 1 cm2·V-1·s-1 after one month as shown in FIGS. 6A and 6B. Additionally and as shown in FIG. 6C, the fluorinated semiconductor exhibited similar drain current maintenance under bias stressing in air after soaking in water over several (e.g., 6) weeks. On the other hand, for neat and crosslinked film, the IDS retention was getting worse over time. Surface plasmon resonance (SPR) measurements of different semiconductor films were performed, with water directly applied on top. This provides a quantitative way to characterize water diffusion kinetics.

In addition, the transistors were also immersed into artificial sweat (pH=8), which contains amino acids, minerals and metabolites. After soaking for 30 days, the mobility of the crosslinked films decreased from 0.8 cm2·V-1·s-1 to 0.05 cm2·V-1·s-1, while the neat film did not show any transistor responses. It was also observed that the neat and crosslinked films degraded much faster in sweat than humid air and water, while the fluorinated film still exhibited a high mobility of 1 cm2 V-1 s-1 after 42 days as shown in FIG. 6D-6F. The advantage of semiconductor surface fluorination is especially obvious in a harsh physiological environment, which again may be due to the hydrophobic nature of perfluorinated chains, making small molecule species (other than water) difficult to adhere to film surface and penetrate inside. These artificial sweat stability results are consistent with the adhesion forces of different semiconductor films, as measured by nanomechanical imaging via AFM and referring to FIG. 3F.

In addition to such experiments demonstrating semiconductor stability in liquids such as water and artificial sweat, further experiments demonstrated photochemical stability. Besides H2O, photo-oxidation can also degrade PSC by light-induced radical generation and thus disrupting backbone conjugation. As reports indicate that substituting atoms on a conjugated polymer with fluorine can prevent 02 diffusion and lower its HOMO energy level (thereby increasing oxidative stability in air), these efforts tested such perfluorinated layer films as additionally improving PSC film photostability. Using PhotoElectron Spectroscopy in Atmosphere (PESA) to detect energy levels of the top surface, it was observed that the fluorinated film exhibited a deepened HOMO of −5.7 eV, compared to −5.2 eV for both neat and crosslinked film. The change in the HOMO energy level originates from the electron-withdrawing ability of perfluorinated chains, thus serving as an interfacial passivation layer and making the semiconductor film less sensitive to oxidation. The HOMO shift was also confirmed by Kevin probe measurements (as in FIG. S31 of the above-referenced U.S. Provisional application). Next, different semiconductor films were exposed to sunlight irradiation in air using a high power of 100 mW·cm-2. It was observed that photo-bleaching occurred for all the semiconductor films upon irradiation, with two regions of lifetime, which correspond to surface (τ1) and bulk (τ2) stability, respectively (FIGS. 6G and 6H). In terms of the surface, the crosslinked films showed a longer lifetime (τ1) than the neat films, which is due to lower concentration of DPPTT component on composite film surface. The present surface fluorination approach can further increase the semiconductor lifetime to 108 min, due to the deepened HOMO level. In terms of bulk film stability (τ2), the neat film showed slower degradation than crosslinked film, which may be due to passivation effect from the oxidized DPPTT semiconductor. However, the fluorinated film is still the most stable one, due to the synergetic effects from both the lowest water absorption and the anti-oxidation properties of perfluorinated layer.

Additionally characterized was the change of semiconductor photoluminescence quantum yield (PLQY) over sun irradiation time. Generally, photo-oxidation generates trap states in PSC film, resulting in a decreased amount of emitted photons and PLQY decay. It was observed that the fluorinated films exhibited slower PLQY degradation than the crosslinked films (FIG. 6I), indicating that the perfluorinated layer serves as protection layer against photo-oxidation. Notably, the neat films did not show any obvious PLQY degradation, due to the large amount of trap states even without sun irradiation.

Via such experimentation, a non-invasive and efficient surface fluorination approach was developed and used to fabricate robust and elastic PSC films. In certain of the examples, a secondary rubber matrix phase is introduced in composite semiconductor film and is used to provide anchoring sites to allow covalent grafting. These anchoring sites can then undergo chemical reactions with functional molecules with high efficiency. This strategy enables a highly stable PSC in OFETs over an extended period under various environments (including air, water/biofluids and sunlight), while simultaneously achieving good mechanical and improved electronic properties. The high PSC environmental stability achieved in connection with the present disclosure is due to the altered film surface properties, specifically the superhydrophobicity and electron-withdrawing ability of the fluorinated layer. Therefore, the permeability of reactive degradation species into PSC film was largely reduced. This developed strategy can be implemented into biosensors, organic light-emitting diodes and organic photovoltaics, allowing functional circuits with prolonged operation lifetimes.

Various example materials were used in the above experimental efforts, and the following discusses examples. Poly-thieno[3,2-b]thiophene-diketopyrrolopyrrole (DPPTT)1, perfluorophenyl azide end-capped polybutadiene (BA)2 and hydrogenated-polybutadiene (BH)2 were synthesized (as discussed in the above-referenced U.S. Provisional application). P2 and P3 SWNT were purchased from Carbon Solutions. Olystyrene-block-poly(ethylene-co-butylene)-block-polystyrene (SEBS) H1052 was provided by Asahi Kasei company. 1H,1H,2H,2H-Perfluorodecanethiol (PFDT), 2-hydroxy-2-methyl-propiophenone, and ethoxynonafluorobutane (99.0%, mixture of two isomers) were purchased from Sigma-Aldrich. Polydimethylsiloxane (PDMS) Sylgard 184 silicone elastomer was purchased from Dow Corning. Artificial sweat was purchased. Other general reagents and solvents were purchased from Sigma-Aldrich or Fisher Scientific. All chemicals were used without further purification.

In terms of general measurement and characterization, employed parameters included number average molecular weight (Mn), weight average molecular weight (Mw), and dispersity (D) of semiconducting polymers, and these aspects were measured using relatively high-quality equipment and materials, for example, by high-temperature gel permeation chromatography (HT-GPC). Histograms of obtained phase images were generated via a 1D statistical function embedded in Gwyddion. Pairing AFM with infrared spectroscopy (AFM-IR), local chemical composition can be acquired by collecting a broadband infrared spectrum on sample surface, where the AFM probe is positioned over a certain location and the infrared laser sweeps through a range of infrared frequencies. Samples are measured using a nanoIR3 AFMIR from Anasys Instruments (Santa Barbara, CA) coupled to a MIRcat-QT™ quantum cascade, mid-infrared laser by Daylight Solutions (frequency range of 917-1700 cm-1 and 1900-2230 cm-1 and repetition rate of 1,470 kHz). AFM-IR data are collected in tapping mode using a gold-coated, AFM probe (spring constant (k): 40 N/m and resonant frequency (fo): 300 kHz). The pulsed, mid-IR laser is tuned to frequencies characteristic of each component as determined by FTIR characterization.

Further, optical microscope images were obtained with a Leica DM4000 M LED microscope. The transistors were measured using a Keithley 4200 semiconductor parameter analyzer (Keithley Instruments Inc, Cleveland, OH, USA) in air. Quartz crystal microbalance (QCM) measurement was performed using QCM200 (Stanford Research Systems) instruments, where the polymers were spin coated and cured on Au-coated quartz crystal sensors (Phillip Technologies). The mass of the polymer coatings was recorded before and after exposure to humid air at regular time intervals to determine mass increase during water absorption. The water diffusion rate was correlated to the mass gain measured via the frequency change of the 1st harmonic oscillator of a quartz crystal using the Sauerbrey Equation (Sauerbrey, Zeitschrift für Physik 1959, 155). The measurements of the frequencies were repeated three times to ensure the accuracy. The error of the mass gain was further calculated via error propagation. Sunlight was used for photostability testing. Photoelectron spectroscopy in air (PESA) measurements were taken on a Riken AC-2 photoelectron spectrometer with a power setting of 5 nW and a power number of 0.5.

In an example calculation of reactive sites, the number was obtained by using BA-to-DPPTT feeding ratio and assuming all the azide end groups of BA reacted with double bonds during crosslinked semiconductor film preparation. In a real-world application, the number is even larger because a small amount of BA reacted with semiconductor alkyl side chain.

The following is a specific example of a surface fluorination procedure according to such experiments of the present disclosure. As a first step, 5 mg/mL DPPTT and 10 mg/mL BA stock solutions were prepared with anhydrous chlorobenzene. Then, the DPPTT solution and the BA solution were mixed with a 2:1 volume ratio to obtain BA/DPPTT blend with a 1:1 weight ratio. The blend solution was heated and stirred under nitrogen at 85° C. for 10 min. The solution was subsequently spin-coated on OTS (octadecyltrimethoxysilane)-modified substrates at 1500 revolutions per minute (r.p.m.) for 1 minute and annealed at 150° C. for 1 hour in glovebox. As a second step, 130 uL PFDT (boiling point: 82° C.) and 5 uL photo initiator (2-hydroxy-2-methyl-propiophenone, boiling point: 76° C.) were mixed in 1 mL F-solvent (ethoxynonafluorobutane) for 10 min. The solution was transferred onto iRUM-s-1:1 film surface. A UV-grade quartz plate was placed on top to spread the solution, followed by UV (365 nm) curing for 10 min in air. The film was washed with F-solvent and IPA to fully remove the residue PFDT and PI. Then the surface-functionalized film was annealed in glove box at 150° C. for 30 min, with film thickness being around 35-40 nm.

Other aspects of the present disclosure involve use of such a film as an encapsulation layer of an electronic and/or material-based functional device for further encapsulation performance (e.g., to further reduce water and oxygen permeability), and in certain specific example, the film-based layer is stacked into multilayers (e.g., by adding one or more inorganic layers).

The following is a specific example of a procedure to fabricate OFETs according to such experiments of the present disclosure. For a rigid transistor, the semiconductor thin films were prepared on OTS-treated SiO2/n++Si substrates, and a top-contact(s) Au (40 nm) were subsequently deposited by thermal evaporation through a shadow mask with channel dimension of length L=50 μm, width W=1000 μm. For the stretchable transistor, a carbon nanotube (CNT) solution for the gate electrode(s) were prepared by dispersing P2-SWNT (0.2 mg/mL) with P3HT (0.05 mg/mL) into chloroform through ultra-sonication for 30 min at 30% amplitude using a 750 W ultrasonication probe, followed by centrifugation at 893.8×g for 30 min. Then the dispersed CNT solution was spray-coated onto OTS-treated Si or SiO2 substrate using a commercial airbrush (Master Airbrush, model SB844-SET) to obtain the gate layer. PDMS-based tough elastomer (PDMS-MPU0.4-IU0.6)3 solution (30 mg/ml in chloroform) was spin-coated onto the gate layer at 3000 r.p.m. for 1 min to form an embedding layer. PDMS (Sylgard 184 [12:1] base vs cross linker in weight ratio) was subsequently spin-coated at 500 r.p.m. for 30 s onto the embedding layer, affording the stretchable substrate. Then the three layers were heated together at 70° C. overnight. The resultant thickness for substrate is around 1 mm. The three layers were peeled off from OTS5 treated substrate, and flipped over. This realizes the gate substrate from bottom to top as PDMS substrate/embedding layer/CNT gate.

A Si/SiO₂ substrate was firstly cleaned with deionized water and isopropanol, followed by 02 plasma for 1-2 min. Then poly(sodium 4-styrenesulfonate), PSSNa solution (3 wt. % in deionized water) was spin-coated onto the substrate at 4000 rpm for 1 min, and annealing at 85° C. for 15 min (thickness: ˜30 nm). The BH/SEBS blend solution in toluene with a designed weight ratio of 4:5 was subsequently spin-coated on PSSNa layer at 1000 rpm for 1 minute, followed by post-annealing in glovebox at 200° C. for 1.5 h to obtain the crosslinked SEBS film (thickness: ˜1.1 μm). The fluorinated semiconductor film (˜35 nm) was directly prepared on the SEBS layer. Then four edges of the Si/SiO₂ substrate were fixed with thick polyimide tapes, followed by immersing into deionized water to release and float the semiconductor/SEBS layers by dissolving the underneath PSSNa layer. Finally, the semiconductor/SEBS layers were taken out, placed onto a gate substrate and dried at room temperature overnight. The polyimide tapes were removed on the next day. Carbon nanotube (CNT) solution for source/drain electrodes was prepared by dispersing P3-SWNT (0.3 mg/mL) in isopropanol through sonicating overnight, followed by ultrasonication for 10 min at 30% amplitude and centrifugation at 503.1×g for 20 min. The dispersed CNT was directly spray-coated onto the semiconductor film through a shadow mask (L=150 μm, W=1000 μm) to obtain the patterned source/drain electrodes.

Accordingly, it is appreciated that such aspects of the present disclosure are directed to enhancing performance in terms of stretchable encapsulation of the stretchable electronic device (whether or not aspects of the surface region include or concern operational stability) and/or in terms of operational stability of the electronic device (whether or not aspects of the surface region include or concern stretchable characteristics). In one specific example, the electronic device includes a stretchable electronic device in the form of at least one of: a stretchable integrated circuit, a solar cell, an organic light emitting diode, an organic photodiode, a battery and a sensor, and the fluorinated layer is covalently attached to the surface region to enhance performance in terms of stretchable encapsulation of the stretchable electronic device. In another specific example, the electronic device includes a stretchable electronic sensor characterized as being one or more of wearable, implantable, operational by continuous sensing, and sensing a point-of diagnosis in a live being, and wherein the fluorinated layer is covalently attached to the surface region to enhance performance in terms of stretchable encapsulation of the stretchable electronic sensor. In yet another specific example, the electronic device includes a stretchable electronic device wherein the surface region is characterized at least in part by providing operational stability (e.g., environmentally as discussed hereinabove) to the electronic device and by it stretchable parameters.

FIGS. 7A and 7B are graphs respectively showing levels of binding energy (eV) versus relative intensity (in arbitrary units) for a crosslinked semiconductor film and for a fluorinated semiconductor film, according to certain exemplary aspects of the present disclosure, with the XPS spectra obtained at different depths of crosslinked film (FIG. 7A) and fluorinated film (FIG. 7B), showing the change of F 1s peak and C 1s peak along film thickness direction. The characteristic peaks of PFDT (CF for F 1s peak, —CF2- and —CF3 for C 1s peak) are only presented on the top surface of fluorinated film, indicating there was no diffusion of F-thiol molecules into bulk crosslinked film during the surface fluorination process.

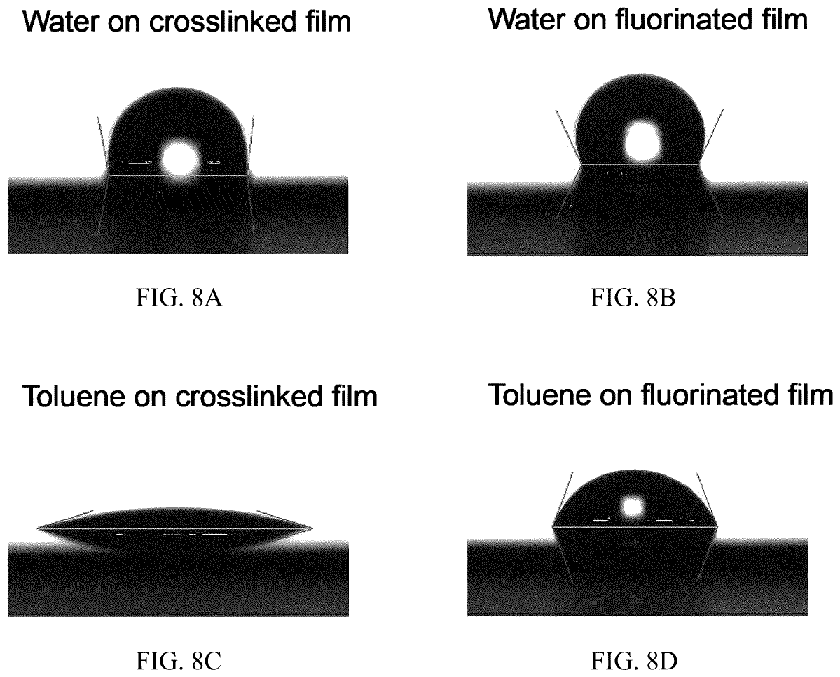

FIGS. 8A, 8B, 8C and 8D are graphs which relate to the films of FIGS. 7A and 7B. More particularly, FIGS. 8A-8D are graphs respectively showing sets of characteristics for water contact angles of: crosslinked film as in FIG. 8A; fluorinated film as in FIG. 8B; sets of characteristics for toluene contact angles of the crosslinked film as in FIG. 8C; and toluene contact angles of the fluorinated film as in FIG. 8D. In connection with these graphs, it is observed that the water contact angle increased from 101.6° to 114.2° after surface fluorination, while the contact angle for toluene increased dramatically from 17.9° to 62.6°.

As also demonstrated in such experimentation, without the presence of non-conjugated C═C from the crosslinked rubber matrix, PFDT cannot be physically absorbed on a neat semiconductor film surface. See the above-referenced U.S. Provisional application (e.g., at Supplementary FIG. S3 with example water contact angles of the neat DPPTT film (S3a) without any treatment and (S3b) following the surface fluorination procedure).

The following Tables S1 and S2 respectively show: the water and toluene contact angles of the crosslinked and fluorinated films (Table Si) and the water contact angles of the neat DPPTT film without or with surface fluorination treatment (Table S2).

Supplementary Table. 1. Water and toluene contact
angles of the crosslinked and fluorinated films.

| Water contact angle | #1 | #2 | #3 | |
|---|---|---|---|---|
| Crosslinked film | 103.65 | 102.44 | 98.6 | 101.6 ± 2.6 |
| Fluorinated film | 114.2 | 114.41 | 113.89 | 114.2 ± 0.3 |
| Toluene contact angle | #1 | #2 | #3 | |
| Crosslinked film | 17.6 | 17.32 | 18.86 | 17.9 ± 0.8 |
| Fluorinated film | 54.55 | 62.6 | 69.5 | 62.2 ± 7.5 |

Supplementary Table. 2. Water contact angles of the neat
DPPTT film without or with surface fluorination treatment.

| Water contact angle | #1 | #2 | 3 | |
|---|---|---|---|---|
| DPPTT film | 108.98 | 109.28 | 109.52 | 109.3 ± 0.3 |
| DPPTT film with surface | 105.91 | 107.38 | 108.66 | 107.3 ± 1.4 |
| fluorination treatment | | | | |

Such experimental efforts also included tuning the fluorination degree through UV exposure dose. Water contact angles of fluorinated semiconductor films with different amount of exposure dose is applied during surface fluorination process. Film thickness is around 35 nm. With the amount of exposure dose increasing, the water contact angle of corresponding fluorinated films increased and stabilized after the exposure dose reached 1800 mJ/cm², indicating saturated surface fluorination. The relative weight ratio of BA versus DPPTT was kept at 1:1 in the crosslinked semiconductor film, and the PFDT solution concentration was fixed at 460 mg/ml. The results indicate that sufficient UV exposure dose is beneficial for complete thiol-ene reaction during surface fluorination.

Example tuning of the fluorination degree through PFDT solution concentration was also performed. For example, with film thickness around 35 nm, water contact angles of fluorinated semiconductor films with different concentration of PFDT solution is applied during surface fluorination process. With PFDT solution concentration increasing, the water contact angle of corresponding fluorinated films increased and stabilized after the thiol concentration reached 230 mg/mL, indicating saturated surface fluorination. The relative weight ratio of BA versus DPPTT was kept at 1:1 in the crosslinked semiconductor film, and the UV exposure dose was fixed at 1800 mJ/cm². The results indicate that it is beneficial if PFDT solution concentration is high enough for complete thiol-ene reaction during surface fluorination.

In connection with example tuning of the fluorination degree through the relative weight ratio of BA versus DPPTT in the crosslinked semiconductor film, XPS spectra was obtained for fluorinated semiconductor films with different weight ratio of BA versus DPPTT, with film thickness around 35 nm. With the weight percentage of BA increasing, the characteristic peaks of PFDT (C—F for F 1s peak, —CF2- for C 1s peak) started to appear and the corresponding intensity increased. The relative XPS peak intensity stabilized after reaching BA/DPPTT (wt/wt)=1:1, indicating saturated surface fluorination. The concentration of PFDT solution was kept at 460 mg/ml, and the UV exposure dose was fixed at 1800 mJ/cm². The results indicate that it is beneficial if sufficient polybutadiene (non-conjugated C═C bonds) is present on the semiconductor film surface to provide enough reactive sites for post modification.

Such experimental efforts also included obtaining two-dimensional Grazing-incidence X-ray diffraction (GIXD) patterns of (a) neat DPPTT film (b) crosslinked film (BA/DPPTT=1:1 in weight ratio) and (c) fluorinated film. (d) Polarization-corrected meridian line cuts along the Qz axis of various semiconductor films. The plots were scaled by illuminated film volume and exposure time. The films were spin-coated on OTS-modified Si substrate for GIXD measurement. All of the semiconductor films exhibited an edge-on orientation, with out-of-plane (h00) lamella stacking peaks and an in-plane (010) π-π stacking peak. The crosslinked film and fluorinated film exhibited identical crystallographic parameters (spacing and coherence length) and diffraction intensity for both lamella and π-π stacking peaks. This indicates that the process of attaching PFDT layer on film surface did not disrupt the crystalline packing of DPPTT in crosslinked semiconductor film.

Related example experiments involving AFM-IR measurement for the fluorinated semiconductor film: (a) showed IR absorption spectrum of DPPTT and PFDT taken by FT-IR (with the non-overlapping characteristic peaks selected for DPPTT and BA being 1660 and 1197 cm-1, respectively); and (b) realized images highlighting the distributions of DPPTT and PFDT (via height and overlay images and via the IR-AFM probing the nanoscale topography and local chemical composition of film surface).

For certain of the bottom-gate top-contact transistors, example/representative output curves were obtained from the bottom-gate top-contact transistors, with (a) neat DPPTT film, (b) crosslinked film (BA/DPPTT=1:1 in weight ratio) or (c) fluorinated film as semiconductor, highly-doped Si as gate electrode, Au (40 nm) as source/drain electrodes (W=1000 μm, L=50 μm) and OTS-modified SiO₂ (300 nm) as dielectrics. Neat film and fluorinated film exhibited the linear behavior at small drain voltage region, indicating good contact between Au and semiconductor. On the other hand, crosslinked film showed nonlinear behavior at small drain voltage, indicating high contact resistance between Au electrode and semiconductor.

Also for certain of the bottom-gate top-contact transistors, example contact resistance was obtained from the transistors with (a) crosslinked film or (b) fluorinated film as semiconductor. Here, the drain voltage was −80 V. Contact resistance was calculated based on the current values at Vg=−80V. Therefore, covalently attaching the fluorinated layer on crosslinked semiconductor film could largely reduce contact resistance.

It was noted that in the obtained transfer curves of the transistors, hysteresis is due to the quality of the wafer being used (e.g., SiO₂ wafer). Even modified with OTS, the SiO₂ wafer still has traps at semiconductor/dielectric interface. DPPTT film does not contain available C═C bonds from polybutadiene for surface fluorination via thiol-ene reaction. The same surface treatment procedure was performed as realized for crosslinked DPPTT film, which has lots of reactive C═C bonds on film surface. This experiment aimed to confirm that the surface fluorination procedure (spread PFDT in F-solvent, followed by UV curing in air, solvent washing and post annealing) did not influence the electrical performance of semiconductor, if the F-thiol molecules weren't covalently grafted onto film surface. On the other hand, this experiment confirmed that the F-thiol molecules did not diffuse into the semiconductor film and dope it during surface fluorination process, without increased off and on drain current.

In related example control experiments (as supporting rationale for the steps in the surface fluorination procedure), bottom-gate top-contact transistors were used with highly-doped Si as gate electrode(s), Au (40 nm) as source/drain electrodes (W=1000 μm, L=50 μm), OTS-modified SiO₂ (300 nm) as dielectrics and crosslinked semiconductor film with different treatment. (a) Crosslinked film with only F-solvent (without PFDT molecules containing) spread on surface, followed by UV curing. (b) Crosslinked film with PFDT solution spread on surface, but without UV curing. In each instance, the semiconductor films underwent post-annealing at 150° C. for 30 min in N₂-filled glovebox to fully get rid of residue.

It was noted that in certain of the experiments, without covalently grafting PFDT molecules onto crosslinked semiconductor film surface via thiol-ene reaction under UV, there was no transistor performance improvement in terms of drain current and threshold voltage. These experiments further confirmed that the improved transistor performance of fluorinated film did not result from the doping effect of F-thiol molecules. On the other hand, the fluorinated layer covalently attached on semiconductor film surface played a central role.

In certain of the successful experiments disclosed herein, bottom-gate top-contact stretchable transistors, with the crosslinked or fluorinated film as a semiconductor, included carbon nanotube serving as gate and source/drain electrodes (e.g., W=1000 μm, L=150 μm), and crosslinked SEBS (e.g., 1.1 μm) as dielectrics.

FIGS. 9A and 9B (corresponding to Supplementary FIGS. 18a and 18b of the above-referenced U.S. Provisional) are sets of representative transfer curves from a bottom-gate top-contact stretchable transistor with a fluorinated film as the semiconductor, according to certain exemplary aspects of the present disclosure, with the respectively-shown sets corresponding to a bottom-gate top-contact stretchable transistor with a fluorinated film as the semiconductor (FIG. 9A) during single stretching, and (FIG. 9B) after multiple stretching-releasing cycles at 50% strain. The charge transport was measured both from parallel (top row) and perpendicular (bottom row) to stretching direction (solid lines for drain current; and dash lines for square root of the drain current). Carbon nanotube (CNT) serves as the gate and source/drain electrodes (with dimensions W=1000 μm, L=150 μm), and crosslinked SEBS (at 1.1 μm) as dielectrics.

For further information regarding such experimentation as disclosed in connection with certain of the figures and example aspects disclosed herein, reference may be made to the above-referenced U.S. Provisional application (see, e.g., above-referenced U.S. Provisional application including its FIGS. S1 through S33 which illustrate supplemental aspects of the present embodiments including those shown herein as FIGS. 7A-7B, FIGS. 8A-8D, and FIGS. 9A-9B).

In addition to the semiconductor materials, this technology can be used on different electronic materials in a device to further improve stability. The materials include conductor, dielectric, substrate and encapsulation layer. In some cases, the material itself has reactive sites (C═C) for grafting. In other cases, the material is to blend with another matrix which has reactive sites (C═C) for grafting.

In addition to fluorinated molecules, other grafting molecules that retard water diffusion can also be used to improve device stability, and this technology realizes and demonstrates the efficiency of thiol-ene reaction to graft the layer. The layer can be grafted by other reactions, such as hydrosilylation or azide/C═C cycloaddition.

For such experimental embodiments, exemplary grafting molecules included: (1) Fluorinated thiol with different degree of fluorination and chain length; (2) Fluorinated molecules with different end-groups: azide, diacrylate, and silicon hydride; (3) Fluorinated molecules with double-ended thiol; and (4) Thiol molecules with different kinds of backbones and length: polydimethylsiloxane (PDMS), alkyl chains and phenyl. Exemplary chemical structures of such molecules are shown as chemical structures (as Example 1, Example 2, Example 3, . . . Example 35) in the above-referenced U.S. Provisional application.

For such experimental embodiments, exemplary matrices (e.g., corresponding to one or more of each matrix discussed above) included: (1) poly(styrene-butadiene-styrene), (2) poly(styrene-isoprene-styrene), (3) polybutadiene, (4) (5) polyisoprene (natural rubber), (6) (7) polydimethylsiloxane (PDMS), (8) poly(styrene-ethylene-butylene-styrene), (9) poly(styrene-isobutylene-styrene), (10) parylene, (11) polyethylene, (12) polypropylene, (13) polyvinylidene fluoride (PVDF), (14) poly(vinylidene fluoride)-co-hexafluoropropylene (PVDF-HFP). These exemplary matrices are shown as chemical structures the above-referenced U.S. Provisional application.

According to the present disclosure and in view of the above, it is appreciated that certain specific examples of surface regions (or “coatings”) are “relatively” thin to maintain flexible mechanical properties and interfacial stability of the devices and in operation of the devices, the devices also evidence good mechanical behavior (and also ensure long term stability of their electronic properties without degradation). In some instances, this is in contrast to specific implementations in which inorganic coatings are used and render the devices to be stiff or brittle. Some of these certain specific examples, applicable for example to organic photovoltaics (OPVs) and organic light-emitting devices (OLEDs), are unique relative to inorganic devices (e.g., photovoltaics, thin-film transistors and LCDs) in that they are characterized as being ultra-flexible, stretchable and/or with foldable barriers; such inorganic devices are exemplified as having an encapsulation-layer thickness (as in exemplary surface regions with low water transmission rate and/or robust interface as set forth in examples of the present disclosure) in a range of less than 10 nm to 10k nm with a corresponding range of Water Vapour Transmission Rate of 10⁻⁵ to 10⁻⁷ (WVTR, g/m²/day) or better. In connection with certain of these examples of the present disclosure, an exciting discovery has been realized in that a stretchable, nanostructured fluorinated molecular protection layer (F-MPL) can have multiple orders lower water permeability (e.g., three orders) than typically reported encapsulation polymers (and such F-MPL examples include a stretchable all-organic nanolayer that has water permeability even on par with (or substantially corresponding to the water permeability of) similarly-constructed inorganic devices). In a specific one of the above-discussed experimental examples, the water permeability of such the F-MPL was measured as being better than a 1×10⁻²² m² s⁻¹ Pa⁻¹ (and in one consistent and successful set of experiments, measured as 5.21×10⁻²² m² s⁻¹ Pa⁻¹), thereby emphasizing how examples of the present disclosure realize impressively low water permeability which is unique relative to previously-reported stretchable polymer encapsulation efforts (e.g., using measured values in terms of WVTR).

Further, in certain of these examples involving organic electronics overcoming environmental instability includes polymer surface functionalization methods to prepare this F-MPL layer, thereby providing significantly improved long-term operational stability and ambient photostability of stretchable polymer semiconductor thin films in harsh environments. In specific examples including at least one of the above-disclosed examples of the present disclosure, the nanometer-thick F-MPL's protection effect on organic field-effect transistors (OFETs) even outperformed various micrometer-thick stretchable polymer encapsulants. These above-disclosed examples of the present disclosure may be used as surface regions (e.g., coatings) on a variety of stretchable and flexible devices including but not limited to as sensors, organic light emitting diodes, solar cells and batteries.

Many different types of processes, devices and applications may be advantaged by incorporating them with aspects as disclosed in the present disclosure, including the related examples in the identified references of the above-identified U.S. Provisional application. In connection with the present disclosure and/or the above-identified U.S. Provisional application, these references are identified with specificity by reference numerals shown inside brackets [#] including but not necessarily limited to those numbered 1 through 31.

It is recognized and appreciated that as specific examples, the above-characterized figures and discussion are provided to help illustrate certain aspects (and advantages in some instances) which may be used in the manufacture of such structures and devices. These structures and devices include the exemplary structures and devices described in connection with each of the figures as well as other devices, as each such described embodiment has one or more related aspects which may be modified and/or combined with the other such devices and examples as described hereinabove may also be found in the drawings and appendix of the above-referenced Provisional Application. As a specific example, reference to a perfluorinated structure or layer or a fluorinated structure or layer may, in certain contexts and examples be represented by any one or more of various corresponding structures including a perfluorinated or fluorinated monolayer.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably coupleable,” to each other to achieve the desired functionality. Specific examples of operably coupleable include but are not limited to physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

The skilled artisan would also recognize various terminology as used in the present disclosure. As examples, the Specification may describe and/or illustrates aspects useful for implementing the examples by way of various semiconductor materials/circuits which may be illustrated as or using terms such as layers, blocks, modules, device, system, unit, controller, and/or other circuit-type depictions, and in contexts as provided the term electronic device refers to one or more of a semiconductor element such as a transistor, an optical element, and a photovoltaic element (e.g., light-emitting diodes and/or photovoltaic components). Also, in connection with such descriptions, the term “source” may refer to source and/or drain interchangeably in the case of a transistor structure. Such semiconductor and/or semiconductive materials (including portions of semiconductor structure) and circuit elements and/or related circuitry may be used together with other elements to exemplify how certain examples may be carried out in the form or structures, steps, functions, operations, activities, etc. It would also be appreciated that terms to exemplify orientation, such as upper/lower, left/right, top/bottom and above/below, may be used herein to refer to relative positions of elements as shown in the figures. It should be understood that the terminology is used for notational convenience only and that in actual use the disclosed structures may be oriented different from the orientation shown in the figures. Thus, the terms should not be construed in a limiting manner. Further, unless otherwise noted, the use of the words “approximate,” “about,” “around,” “substantially,” etc., mean plus or minus ten percent.

Based upon the above discussion and illustrations, those skilled in the art will readily recognize that various modifications and changes may be made to the various embodiments without strictly following the exemplary embodiments and applications illustrated and described herein. For example, methods as exemplified in the Figures and/or description may involve steps carried out in various orders, with one or more aspects of the embodiments herein retained, or may involve fewer or more steps, unless specified differently above. Also, two or more steps may be performed concurrently or with partial concurrence, unless specified differently above.

What is claimed:

1. A method comprising:
providing a fluorinated layer covalently attached to a surface region in the form of a composite layer or film which is densified through covalently-attached fluorination molecules, to enhance performance of the surface region in terms of one or more parameters, said one or more parameters including or characterizing: operational stability of the surface region, or a manner of degree to which an electronic device is protected by the surface region, the surface region including or corresponding to a polymer film, and encapsulation performance associated with the surface region including or corresponding to a stretchable material protecting an electronic device.

2. The method of claim 1, further including covalently grafting perfluorinated chains onto the surface region through surface functionalization, and using the perfluorinated chains to protect against or mitigate diffusion of water or other liquid into the surface region, thereby enhancing permeability reduction of the surface region.

3. The method of claim 1, further including fixing morphology and introducing surface reactive sites simultaneously, and wherein said providing a fluorinated layer covalently attached to the surface region includes at least one of: causing the fluorinated layer to be covalently attached to the surface region; and using the surface region and the fluorinated layer in a cooperative configuration with a semiconductor in an environment characterized by one or more of relative humidity of greater than twenty percent, and immersion of the surface region in a bio-based fluid.

4. The method of claim 1, wherein the surface region and the fluorinated layer are cooperatively configured as part of a composite semiconductor film having: conjugated polymer interpenetrating with a crosslinked rubber matrix; or a rubber matrix phase in a crosslinked composite semiconductor film.

5. The method of claim 1, further including: introducing non-conjugated C═C bonds as reactive sites on the surface region and performing subsequent surface modification by reaction between the reactive sites and a fluorinated or hydrophobic reactive molecule via light or heat.

6. The method of claim 1, wherein the surface region and the fluorinated layer are cooperatively configured as part of a composite semiconductor film of a semiconductor including an organic-field-effect transistor (OFET) characterized by a maintainable charge carrier mobility characterized as decreasing by less than sixty percent over fifty days being soaked in water.

7. The method of claim 1, wherein the surface region and the fluorinated molecules are cooperatively configured as part of a composite semiconductor film of a semiconductor, and the method further includes subjecting the semiconductor to at least one harsh environment condition that includes storing the semiconductor with the composite semiconductor film in humid air for at least eight weeks, and confirming stable operation of the semiconductor while the semiconductor manifests a charge carrier mobility at or above 1 cm²·V⁻¹·s⁻¹.

8. The method of claim 1, wherein the surface region and the fluorinated molecules are cooperatively configured as part of a composite semiconductor film of a semiconductor, and the method further includes subjecting the semiconductor to at least one harsh environment condition that includes immersion of at least the semiconductor film in a bio-based fluid for at least five weeks, and confirming stable operation of the semiconductor while the semiconductor manifests a charge carrier mobility at or above ˜1 cm²·V⁻¹·s⁻¹.

9. The method of claim 1, further including using a rubber matrix phase in a composite semiconductor film to provide anchoring sites to facilitate covalent grafting.

10. An apparatus comprising:
a stretchable composite film including a polymer material having at least a portion of the polymer material being densified through covalently-attached fluorination molecules.

11. The apparatus of claim 10, further including an electronic device to which the composite film is attached, wherein the electronic device is operationally stable due to the covalently-attached fluorination molecules, and the polymer material is characterized as being non-conjugated and with crystalline packing.

12. An apparatus comprising:
a surface region, in the form of a layer or film, including or corresponding to a polymer material; and
fluorinated molecules covalently attached to the surface region and acting to densify the surface region and enhance performance of the surface region in terms of one or more parameters, said one or more parameters including or characterizing: operational stability of the surface region, or a manner of degree to which an electronic device is protected by the surface region.

13. The apparatus of claim 12, further including an electronic device including one or more of: an optical element and a semiconductor element, wherein the surface region and the fluorinated molecules are cooperatively configured as part of a composite semiconductor film of the electronic device, and wherein the one or more parameters include encapsulation performance associated with the surface region including or corresponding to a stretchable material protecting the electronic device.

14. The apparatus of claim 12, further including a semiconductor having a rubber matrix phase in a crosslinked composite semiconductor film, wherein the rubber matrix phase in the crosslinked composite semiconductor film includes the surface region and the fluorinated molecules being cooperatively configured to facilitate stability of the surface region.

15. The apparatus of claim 12, further including an organic-field-effect transistor (OFET), wherein the surface region, including the covalently-attached fluorinated molecules, is configured as part of a composite semiconductor film of the OFET.

16. The apparatus of claim 12, wherein the surface region and the fluorinated molecules are cooperatively configured as part of a composite semiconductor film of an organic-field-effect transistor (OFET) characterized by a charge carrier mobility that is maintainable at or above 1 cm²·V⁻¹·s⁻¹.

17. The apparatus of claim 12, wherein the surface region includes a crosslinked composite semiconductor portion, and further includes covalently-grafted perfluorinated chains attached on the crosslinked composite semiconductor portion.

18. The apparatus of claim 12, wherein the surface region, with the fluorinated molecules covalently attached to the surface region, is characterized in that the surface region maintains substantially the same level of stretchability and charge transport mobility after N stretching-releasing cycles under at least 50% strain, wherein N is an integer in a range from 2 to 1000.

19. The apparatus of claim 12, wherein the fluorinated molecules are uniformly dispersed on the surface region or into the surface region, and are to provide a base surface or platform for one or more subsequent modifications.

20. The apparatus of claim 12, wherein the surface region is characterized as being operationally stable due to the fluorinated molecules being covalently attached to the surface region and in having a surface reactive sites and morphology being fixed concurrently.

21. The apparatus of claim 12, wherein the electronic device includes a stretchable electronic device in the form of at least one of: a stretchable integrated circuit, a solar cell, an organic light emitting diode, an organic photodiode, a battery and a sensor, and the fluorinated molecules are covalently attached to the surface region to enhance performance in terms of stretchable encapsulation of the stretchable electronic device.

22. The apparatus of claim 12, wherein the electronic device includes a stretchable electronic sensor characterized as being one or more of wearable, implantable, operational by continuous sensing, and sensing a point-of diagnosis in a live being, and wherein the fluorinated molecules are covalently attached to the surface region to enhance performance in terms of stretchable encapsulation of the stretchable electronic sensor, and the stretchable electronic sensor includes receptors attached onto a stretchable polymer of the sensor.
